(19) United States
(12) Patent Application Publication
(10) Pub. No.: US 2015/0194460 A1
(43) Pub. Date: Jul. 9, 2015

(54) MANUFACTURING METHOD OF SEMICONDUCTOR DEVICE

(71) Applicant: RENESAS ELECTRONICS CORPORATION, Kanagawa (JP)

(72) Inventor: Koji MAEKAWA, Kanagawa (JP)

(21) Appl. No.: 14/586,712

(22) Filed: Dec. 30, 2014

(30) Foreign Application Priority Data
Jan. 8, 2014 (JP) 2014-001883

(51) Int. Cl. H01L 27/146

(52) U.S. Cl. CPC H01L 27/14667; H01L 27/14625; H01L 27/14685; H01L 27/14621

(57) ABSTRACT

A manufacturing procedure of a semiconductor device is simplified. In a manufacturing method of a semiconductor device, in each of regions AR with pixels for detecting different colored lights, a liner film LF1 is formed over an interlayer insulating film IL formed to cover a photodiode PD. Then, an opening OP is formed to reach a midway point of the interlayer insulating film IL while penetrating the liner film LF1. The liner film LF1 is formed such that the thickness of the liner film LF1 is varied among the respective regions AR. A height position of a bottom surface of the opening OP in a region with the thin liner film LF1 is lower than a height position of a bottom surface of the opening OP in a region with the thick liner film LF1.

### CROSS-REFERENCE TO RELATED APPLICATIONS

The disclosure of Japanese Patent Application No. 2014-001883 filed on Jan. 8, 2014 including the specification, drawings and abstract is incorporated herein by reference in its entirety.

### BACKGROUND

The present invention relates to manufacturing methods of semiconductor devices, and more particularly to a technique that can be suitably applied to a manufacturing method of a semiconductor device including, for example, a solid-state imaging element.

Complementary metal oxide semiconductor (CMOS) image sensors using a CMOS have been developed as the solid-state imaging element (hereinafter also simply referred to as an imaging element) used in a digital camera or the like. The CMOS image sensor includes a plurality of pixels arranged in a matrix for respectively detecting light. Each of the pixels is provided with a photoelectric conversion element, such as a photodiode, for detecting light in each color, for example, red, blue, or green to generate an electric charge. Over each of the photodiodes, a color filter for transmitting the light in any one of different specific colors, such as red, blue, and green, is formed. The light in the specific color having passed through the color filter enters the photodiode.

In such a CMOS image sensor, in order to improve the efficiency of incidence of the light on each pixel together with an increase in the number of pixels and miniaturization of the pixels, an optical waveguide is formed above the photodiode in each pixel.

In a technique disclosed in Japanese Unexamined Patent Application Publication No. 2010-212535 (Patent Document 1), a substrate is provided with a pixel array which includes a plurality of pixels with photoelectric conversion portions for receiving different colored lights to perform photoelectric conversion of the light, and optical waveguides are formed in a wiring layer located over the substrate to guide the lights to the respective photoelectric conversion portions of the pixels.

### RELATED ART DOCUMENTS

### Patent Documents

### [Patent Document 1]

Japanese Unexamined Patent Application Publication No. 2010-212535

### SUMMARY

When the optical waveguide is formed above the photodiode in this way, it is desirable that the efficiency of detection of the light by the photodiode is maximized in the pixel for detecting every colored light, for example, each of red, green, and blue lights. Further, in order to maximize the efficiency of detection of the light in the respective pixels for detecting the different colored lights, a distance between a lower surface of the optical waveguide and an upper surface of the corresponding photodiode is desired to be changed depending on the wavelength of the light incident on the photodiode.

Specifically, the photodiode is formed over the main surface of the semiconductor substrate, followed by formation of an interlayer insulating film and a wiring layer thereover. Then, when forming openings for the optical waveguide by etching the wiring layer and interlayer insulating film, for example, an etching time can also be adjusted to vary a height position of a bottom surface of the opening in each of the pixels for detecting the different colors. In this case, however, an etching process for etching the wiring layer and interlayer insulating film has to be independently performed on each of the pixels for detecting the different colors, which leads to a complicated manufacturing procedure of the semiconductor device.

Other problems and new features of the present invention will be clearly understood by the following description of the present specification in connection with the accompanying drawings.

In a manufacturing method of a semiconductor device according to one embodiment of the invention, a second film as a liner film is formed over a first film including an interlayer insulating film formed to cover a photodiode, in each of regions with pixels for detecting different colored lights. Thereafter, an opening is formed to reach a midway point of the first film while penetrating the second film. The second film is formed such that the thickness of the second film is varied among the regions. A height position of a bottom surface of the opening in a region with the thin second film is lower than a height position of a bottom surface of the opening in a region with the thick second film.

According to the embodiment of the present invention, the manufacturing procedure of the semiconductor device can be simplified.

### BRIEF DESCRIPTION OF THE DRAWINGS

FIG. 1 is a cross-sectional view showing the structure of a semiconductor device according to one embodiment of the invention;

FIG. 2 is a manufacturing process flowchart showing parts of manufacturing steps of the semiconductor device in the embodiment;

FIG. 3 is a cross-sectional view of a main part of one manufacturing step of the semiconductor device in the embodiment;

FIG. 4 is a cross-sectional view of a main part of another manufacturing step of the semiconductor device in the embodiment;

FIG. 5 is a cross-sectional view of a main part of another manufacturing step of the semiconductor device in the embodiment;

FIG. 6 is a cross-sectional view of a main part of another manufacturing step of the semiconductor device in the embodiment;

FIG. 7 is a cross-sectional view of a main part of another manufacturing step of the semiconductor device in the embodiment;

FIG. 8 is a cross-sectional view of a main part of another manufacturing step of the semiconductor device in the embodiment;

FIG. 9 is a cross-sectional view of a main part of another manufacturing step of the semiconductor device in the embodiment;

FIG. 10 is a cross-sectional view of a main part of another manufacturing step of the semiconductor device in the embodiment;

FIG. 11 is a cross-sectional view of a main part of another manufacturing step of the semiconductor device in the embodiment;

FIG. 12 is a cross-sectional view of a main part of another manufacturing step of the semiconductor device in the embodiment;

FIG. 13 is a cross-sectional view of a main part of another manufacturing step of the semiconductor device in the embodiment;

FIG. 14 is a manufacturing process flowchart showing parts of manufacturing steps of a semiconductor device in a comparative example;

FIG. 15 is a cross-sectional view of a main part of one manufacturing step of the semiconductor device in the comparative example;

FIG. 16 is a cross-sectional view of a main part of another manufacturing step of the semiconductor device in the comparative example;

FIG. 17 is a cross-sectional view of a main part of another manufacturing step of the semiconductor device in the comparative example; and

FIG. 18 is a cross-sectional view of a main part of another manufacturing step of the semiconductor device in the comparative example.

### DETAILED DESCRIPTION

The following preferred embodiments of the invention may be described below by being divided into a plurality of sections or embodiments for convenience, if necessary, which are not independent from each other unless otherwise specified. One of the sections or embodiments may be a modified example, a detailed description, or supplementary explanation of a part or all of the other.

Even when referring to a specific number about an element and the like (including the number of elements, a numerical value, an amount, a range, and the like) in the embodiments below, the invention is not limited to the specific number, and may take the number greater than, or less than the specific numeral number, unless otherwise specified, and except when limited to the specific number in principle.

It is obvious that the components (including steps) in the embodiments below are not necessarily essential unless otherwise specified, and except when clearly considered to be essential in principle. Likewise, when referring to the shape of one component, or the positional relationship between the components in the following embodiments, any shape or positional relationship substantially similar or approximate to that described herein may be included in the invention unless otherwise specified and except when clearly considered not to be so in principle. The same goes for the above numerical value, and the range.

Typical preferred embodiments of the invention will be described in detail below based on the accompanying drawings. In all drawings for explaining the embodiments, members having the same functions are indicated by the same or similar reference characters, and the repeated description thereof will be omitted. In the following embodiments, the same or similar parts will not be repeatedly described in principle unless absolutely necessary.

In the accompanying drawings used in the embodiments, even some cross-sectional views may omit hatching for better understanding.

### Preferred Embodiments

### <Structure of Semiconductor Device>

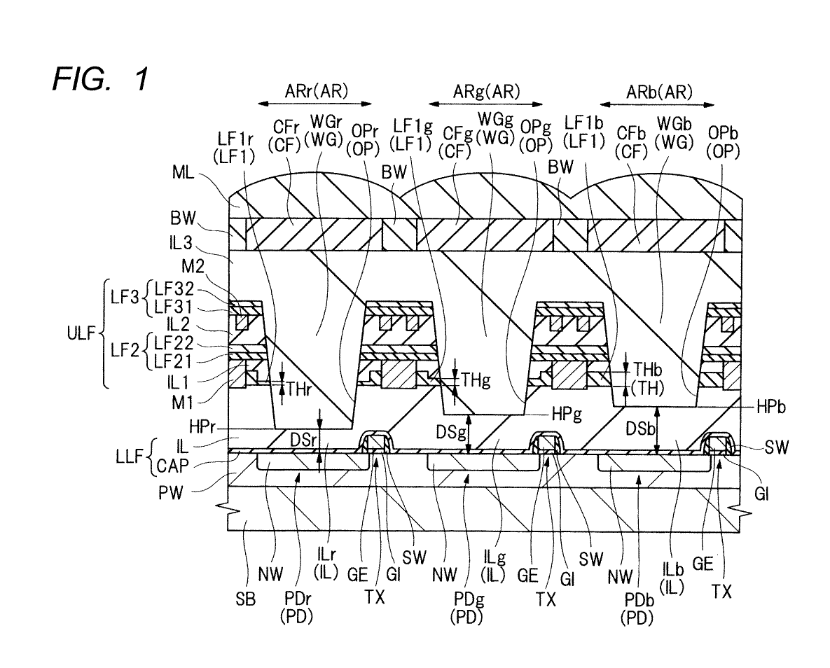

First, the structure of an imaging element as a semiconductor device in one embodiment of the invention will be described. FIG. 1 shows a cross-sectional view of the structure of the semiconductor device in the one embodiment.

The imaging element as the semiconductor device of the present embodiment includes a plurality of kinds of pixels for detecting different colored lights.

As shown in FIG. 1, the imaging element as the semiconductor device of the present embodiment includes a semiconductor substrate SB made of, for example, monocrystalline silicon (Si) or the like. The semiconductor substrate SB has a plurality of regions AR with pixels formed thereat, at the upper surface as a main surface thereof. The respective regions AR are arranged in a matrix in a first direction within the upper surface or plane as the main surface of the semiconductor substrate SB, as well as in a second direction intersecting the first direction within the upper surface as the main surface of the semiconductor substrate SB. That is, the semiconductor substrate SB has a pixel region in which the regions AR with pixels formed therein are arranged in the matrix, over its upper surface as the main surface of the semiconductor substrate SB.

Each of the regions AR is provided with a pixel serving as a light receiving section of the imaging element. Thus, the pixels are arranged in a matrix in the first direction within the upper surface as the main surface of the semiconductor substrate SB, as well as in the second direction intersecting the first direction within the upper surface as the main surface of the semiconductor substrate SB.

Note that the semiconductor substrate SB may have a peripheral circuit region (not shown) arranged side by side with the pixel region over the upper surface as the main surface of the semiconductor substrate SB. The peripheral circuit region includes not a light receiving section, but for example, a transistor for use in a switch or the like that can operate at high speed, a wiring layer thereover, and the like.

Each of the regions AR includes a photodiode PD forming each pixel, a transfer transistor TX, an amplification transistor, and the like. The photodiode PD is a photoelectric conversion element that receives the incident light to convert the light into electric charge. The transfer transistor TX is a transistor that transfers the electric charges generated by conversion of the incident light by the photodiode. Each pixel also includes parts located above the photodiode PD, namely, an optical waveguide WG and a color filter CF to be described later.

A p-type semiconductor layer PW with p-type impurities, such as boron (B), introduced thereinto is formed on the side of an upper surface of the semiconductor substrate SB across the regions AR. On the other hand, in each of the regions AR, an n-type semiconductor layer NW with n-type impurities, such as phosphorus (P) or arsenic (As), introduced thereinto is formed in an upper layer part of the p-type semiconductor layer PW. Thus, in each of the regions AR, the p-type semiconductor layer PW is formed directly under the n-type semiconductor layer NW. The p-type semiconductor layer PW and the n-type semiconductor layer NW form a p-n junction to thereby configure the photodiode PD.

For example, a photodiode PDr is formed in a region ARr where a pixel for incidence of red (R) light is formed, at the upper surface as the main surface of the semiconductor substrate SB. A photodiode PDg is formed in a region ARg where a pixel for incidence of green (G) light is formed, at the upper surface as the main surface of the semiconductor substrate SB. A photodiode PDb is formed in a region ARb where a pixel for incidence of blue (B) light is formed, at the upper surface as the main surface of the semiconductor substrate SB. The photodiode PDr is a photoelectric conversion element that receives the red (R) incident light to convert the light into electric charge. The photodiode PDg is a photoelectric conversion element that receives the green (G) incident light to convert the light into electric charge. The photodiode PDb is a photoelectric conversion element that receives the blue (B) incident light to convert the light into electric charge.

A gate electrode GE made of, for example, a polysilicon film is formed over the upper surface of the semiconductor substrate SB via a gate insulating film GI made of, for example, a silicon oxide film. Sidewalls SW made of, for example, a silicon oxide film are formed over the side surfaces of each gate electrode GE. The gate electrode GE is a gate electrode for the transfer transistor TX. On the other hand, the n-type semiconductor layer NW included in the photodiode PD also serves as a source region of the transfer transistor TX.

FIG. 1 omits the illustration of a drain region of the transfer transistor TX. The photodiode PD is coupled to a transistor, such as the amplification transistor for amplifying a signal output from the photodiode PD, via the transfer transistor TX. Here, FIG. 1 shows only the transfer transistor TX, and omits the illustration of an element isolation region and the like.

In each of the regions ARr, ARg, and ARb, an interlayer insulating film IL made of, for example, a silicon oxide film, is formed over the upper surface of the semiconductor substrate SB to cover the photodiode PD and the transfer transistor TX. The upper surface of the interlayer insulating film IL is planarized by a chemical mechanical polishing (CMP) method or the like.

Apart of the interlayer insulating film IL located above the photodiode PDr in the region ARr is hereinafter referred to as a part ILr. A part of the interlayer insulating film IL located above the photodiode PDg in the region ARg is hereinafter referred to as apart ILg. Apart of the interlayer insulating film IL located above the photodiode PDb in the region ARb is hereinafter referred to as a part ILb.

That is, the part ILr is a part of the interlayer insulating film IL positioned over the photodiode PDr in the region ARr. The part ILg is a part of the interlayer insulating film IL positioned above the photodiode PDg in the region ARg. The part ILb is a part of the interlayer insulating film IL positioned over the photodiode PDb in the region ARb.

A cap insulating film CAP made of, for example, a silicon nitride film may be formed over the upper surface of the photodiode PD, the upper surface of the gate electrode GE, and the surfaces of the sidewalls SW formed at the side surfaces of the gate electrode GE. In this case, the interlayer insulating film IL is formed over the photodiode PD and the transfer transistor TX via the cap insulating film CAP.

After forming the interlayer insulating film IL, a plurality of contact plugs (not shown) can be formed to reach the semiconductor substrate SB through the interlayer insulating film IL. In this case, the upper surfaces of the contact plugs and the upper surface of the interlayer insulating film IL are planarized by the CMP method or the like.

A liner film LF1, which is made of an insulating film, for example, a silicon carbonitride film (SiCN), is formed over the interlayer insulating film IL1. The liner film LF1 is a protective film for protecting the interlayer insulating film IL.

A part of the liner film LF1 located above the part ILr of the interlayer insulating film IL in the region ARr is hereinafter referred to as a part LF1r. A part of the liner film LF1 located above the part ILg of the interlayer insulating film IL in the region ARg is hereinafter referred to as a part LF1g. A part of the liner film LF1 located above the part ILb of the interlayer insulating film IL in the region ARb is hereinafter referred to as a part LF1b.

That is, the part LF1r is the liner film LF1 positioned above the photodiode PDr in the region ARr. The part LF1g is the liner film LF1 positioned above the photodiode PDg in the region ARg. The part LF1b is the liner film LF1 positioned above the photodiode PDb in the region ARb.

A thickness THr of the part LF1r, a thickness THg of the part LF1g, and a thickness THb of the part LF1b differ from one another. Thus, when forming openings OP reaching a midway point of the interlayer insulating film IL in the thickness direction thereof by etching the respective layers from the liner film LF3 to the liner film LF1, the height position of the bottom surface of the opening OP can be varied among the regions ARr, ARg, and ARb.

Specifically, the wavelength of the red light incident on the region ARr is longer than that of the green light incident on the region ARg. The wavelength of the green light incident on the region ARg is longer than that of the blue light incident on the region ARb. At this time, the thickness THr of the part LF1r is smaller than the thickness THg of the part LF1g, and the thickness THg of the part LF1g is smaller than the thickness THb of the part LF1b. Thus, when forming the openings OP reaching a midway point of the interlayer insulating film IL in the thickness direction thereof by etching the respective layers from the liner film LF3 to the liner film LF1, the height position of the bottom surface of the opening OP can be decreased with increasing wavelength of the incident light among the respective regions ARr, ARg, and ARb.

An interlayer insulating film IL1 made of, for example, a silicon oxide (SiO₂) film, is formed over the liner film LF1.

Between the respective adjacent regions ARr, ARg, and ARb, the interlayer insulating film IL1 and the liner film LF1 are provided with a plurality of wiring trenches that penetrate the interlayer insulating film IL1 and the liner film LF1. For example, a copper (Cu) film is embedded in each of the wiring trenches to thereby form a wiring M1 inside each of the wiring trenches. The wiring M1 is electrically coupled to the semiconductor element, such as the photodiode PD or transfer transistor TX, formed at the upper surface of the semiconductor substrate SB via the contact plug.

The liner film LF1, the interlayer insulating film IL1, and the wiring M1 form a first wiring layer.

The wirings M1 are formed between the respective regions AR, whereby when the light enters the photodiode PD formed in each of the respective regions AR, the incident light can be prevented or suppressed from being blocked by the wiring M1. The respective upper surfaces of the wiring M1 and the interlayer insulating film IL1 may be planarized by the CMP method or the like.

A liner film LF2 is formed over the interlayer insulating film IL1 and the wiring M1. The liner film LF2 is formed of a laminated insulating film including an insulating film LF21 made of, for example, a silicon carbonitride (SiCN) film, and an insulating film LF22 made of, for example, an oxygen-containing silicon carbide (SiCO) film. The liner film LF2 is a protective film for protecting the interlayer insulating film IL1 and the wiring M1.

Alternatively, the liner film LF2 is a diffusion preventing film for preventing the diffusion of material included in the wiring M1, for example, copper (Cu).

An interlayer insulating film IL2 made of, for example, a carbon-containing silicon oxide (SiOC) film, is formed over the liner film LF2.

Between the respective adjacent regions ARr, ARg, and ARb, the interlayer insulating film IL2 has a plurality of wiring trenches on its upper surface of the interlayer insulating film IL2. A plurality of via holes (not shown) is formed at the bottom surface of each wiring trench to penetrate the interlayer insulating film IL2. For example, a copper (Cu) film is embedded in the respective wiring trenches and via holes to thereby form the wirings M2 in the wiring trenches, and form vias (not shown) in the via holes. The wiring M2 is electrically coupled to the wiring M1 through the via.

The liner film LF2, the interlayer insulating film IL2, the wiring M2, and the above-mentioned vias (not shown) form a second wiring layer.

The wirings M2 are formed between the respective regions AR. When the light enters the photodiode PD formed in each of the respective regions AR, the incident light can be prevented or suppressed from being blocked by the wirings M2. The respective upper surfaces of the wiring M2 and the interlayer insulating film IL2 may be planarized by the CMP method or the like.

A liner film LF3 is formed over the interlayer insulating film IL2 and the wiring M2. The liner film LF3 is formed of a laminated insulating film including an insulating film LF31 made of, for example, a silicon carbonitride (SiCN) film, and an insulating film LF32 made of, for example, an oxygen-containing silicon carbide (SiCO) film. The liner film LF3 is a protective film for protecting the interlayer insulating film IL2 and the wiring M2. Alternatively, the liner film LF3 is a diffusion preventing film for preventing the diffusion of material included in the wiring M2, for example, copper (Cu).

In this way, the interlayer insulating film IL, the first wiring layer comprised of the liner film LF1, interlayer insulating film IL1, and wiring M1, the second wiring layer comprised of the liner film LF2, interlayer insulating film IL2, and wiring M2, and the liner film LF3 are formed over the semiconductor substrate SB from the lower side to the upper side thereof in that order. The interlayer insulating film IL and the cap insulating film CAP which are formed under the liner film LF1 are hereinafter referred to as a lower layer film LLF. The interlayer insulating film IL1, liner film LF2, interlayer insulating film IL2, and liner film LF3 which are formed above the liner film LF1 are hereinafter referred to as an upper layer film ULF. At this time, the lower layer film LLF, the liner film LF1, and the upper layer film ULF are formed over the semiconductor substrate SB from the lower side to the upper side thereof in that order.

Now, a description will be given of an example in which the thickness of the liner film LF1 included in the first wiring layer is varied among the respective regions ARr, ARg, and ARb, and the height position of the bottom surface of the opening OP is varied among the respective regions ARr, ARg, and ARb. However, among the respective regions ARr, ARg, and ARb, the thickness of the liner film included in any of the wiring layers may be varied, and thus the height position of the bottom surface of the opening reaching the midway point of the interlayer insulating film IL in the thickness direction through the linear film may be varied. Thus, the thickness of the liner film LF2 included in the second wiring layer is varied among the respective regions ARr, ARg, and ARb, and the height of the bottom surface of the opening OP can also be varied among the respective regions ARr, ARg, and ARb.

Alternately, the thickness of the liner film LF3 is varied among the respective regions ARr, ARg, and ARb, so that the height of the bottom surface of the opening OP can also be varied among the respective regions ARr, ARg, and ARb. At this time, the openings are formed to reach the midway points of the lower layer films in the thickness direction under the respective liner films while penetrating the respective liner films with the different thicknesses.

In each of the regions AR, the opening OP is formed to reach the midway point of the interlayer insulating film IL in the thickness direction while penetrating the liner film LF3, the interlayer insulating film IL2, the liner film LF2, the interlayer insulating film IL1, and the liner film LF1.

For example, in the region ARr, the opening OPr is formed to reach the midway point of the interlayer insulating film IL in the thickness direction while penetrating the liner film LF3, the interlayer insulating film IL2, the liner film LF2, the interlayer insulating film IL1, and the liner film LF1. In the region ARg, the opening OPg is formed to reach the midway point of the interlayer insulating film IL in the thickness direction while penetrating the liner film LF3, the interlayer insulating film IL2, the liner film LF2, the interlayer insulating film IL1, and the liner film LF1. In the region ARb, the opening OPb is formed to reach the midway point of the interlayer insulating film IL in the thickness direction while penetrating the liner film LF3, the interlayer insulating film IL2, the liner film LF2, the interlayer insulating film IL1, and the liner film LF1.

When a height position HPr is the height position of the bottom surface of the opening OPr, a height position HPg is the height position of the bottom surface of the opening OPg, and a height position HPb is the height position of the bottom surface of the opening OPb, the height positions HPr, HPg, and HPb differ from one another. Preferably, the height position HPr is lower than the height position HPg, and the height position HPg is lower than the height position HPb. In this way, the distance from the lower surface of the optical waveguide WG to the upper surface of the photodiode PD can be adjusted in the respective pixels for detecting the different colored lights.

An insulating film IL3, which is made of, for example, a silicon nitride film is formed over the liner film LF3 including the inside of the opening OP, whereby the inside of the opening OP is filled with the insulating film IL3. Thus, in the region AR, the optical waveguide WG for guiding the incident light to the photodiode PD is formed above the photodiode PD. The optical waveguide WG is made of the insulating film IL3 embedded in the opening OP.

For example, in the region ARr, the optical waveguide WGr for guiding the red (R) incident light to the photodiode PDr is formed above the photodiode PDr. The optical waveguide WGr is made of the insulating film IL3 embedded in the opening OPr. In the region ARg, the optical waveguide WGg for guiding the green (G) incident light to the photodiode PDg is formed above the photodiode PDg. The optical waveguide WGg is made of the insulating film IL3 embedded in the opening OPg. In the region ARb, the optical waveguide WGb for guiding the blue (B) incident light to the photodiode PDb is formed above the photodiode PDb. The optical waveguide WGb is made of the insulating film IL3 embedded in the opening OPb.

A refractive index of the optical waveguide WG made of, e.g., a silicon nitride film is relatively large, for example, about 1.97. In this way, the refractive index of the optical waveguide WG can be higher than an average refractive index of the wiring layer around the optical waveguide WG, which allows the light incident on the optical waveguide WG through the microlens ML and color filter CF to be guided to the photodiode PD without attenuating the light so much.

Between the regions ARr, ARg, and ARb, a barrier wall BW made of, for example, a silicon oxide film is formed over the corresponding optical waveguide WG.

The color filter CF is formed between the adjacent barrier walls BW. The color filter CF is a filter that transmits light in a specific color, such as red (R), green (G), or blue (B), while not transmitting light in other colors. In other words, the color filter CF is a filter that transmits light with a wavelength in a specific range, while not transmitting light with other wavelengths. Thus, the color filter CF is a film colored in each color, for example, red (R), green (G), or blue (B).

In the region ARr, a red color filter CFr is formed between the adjacent barrier walls BW. In the region ARg, a green color filter CFg is formed between the adjacent barrier walls BW. In the region ARb, a blue color filter CFb is formed between the adjacent barrier walls BW.

The imaging element as the semiconductor device of the present embodiment causes the photodiode PD to receive light incident on the region AR with the pixel formed from the main surface side or upper surface side of the semiconductor substrate SB and then to convert the incident light into electric charge, and reads the converted electric charge as signal information, thereby obtaining an image information data or the like. The light applied to the region AR is incident on the upper surface of the color filter CF, and then enters the photodiode PD while passing through the color filter CF, the optical waveguide WG, and the interlayer insulating film IL.

As shown in FIG. 1, the microlens ML with a convex curved surface as its upper surface may be formed above the color filter CF in each of the regions ARr, ARg, and ARb. The microlens ML is a convex lens having its upper surface curved, and made of a film that can transmit light therethrough. The microlens ML allows the light applied to the region AR with each pixel formed from the main surface side or upper surface side of the semiconductor substrate SB to be collected onto the photodiode PD via the color filter CF, the optical waveguide WG, and the interlayer insulating film IL.

### <Manufacturing Method of Semiconductor Device>

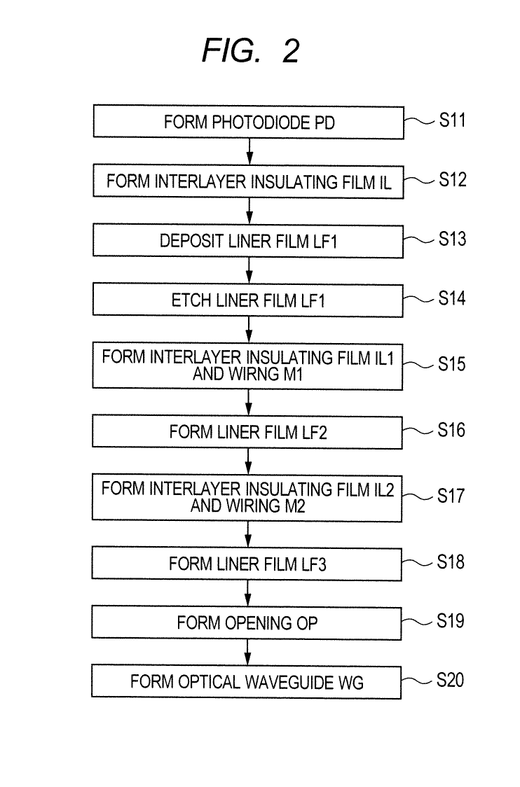

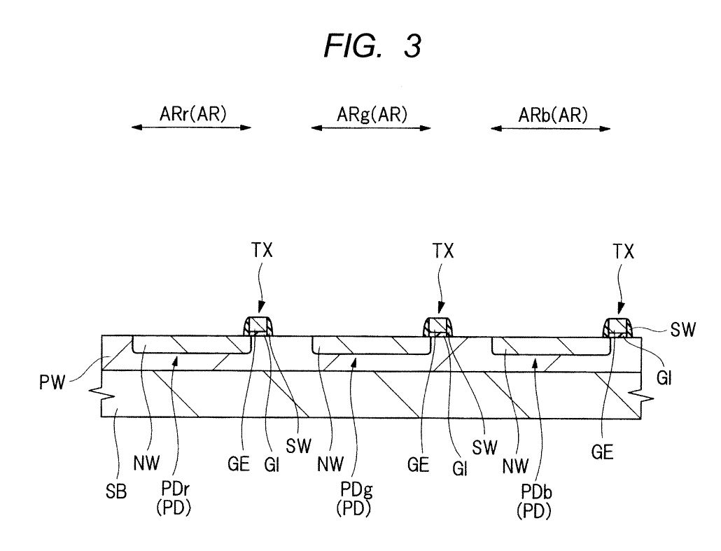

Next, a manufacturing method of the semiconductor device in the present embodiment will be described below. FIG. 2 is a manufacturing process flowchart showing parts of manufacturing steps of the semiconductor device in the embodiment. FIGS. 3 to 13 are cross-sectional views showing main parts of other manufacturing steps of the semiconductor device in the embodiment.

First, the photodiode PD is formed (in step S11 of FIG. 2) In step S11, first, as shown in FIG. 3, the semiconductor substrate SB made of, for example, a monocrystalline silicon (Si) is provided. The semiconductor substrate SB has a plurality of regions AR with pixels formed thereat, over the upper surface as a main surface thereof. The respective regions AR are arranged in a matrix in the first direction within the upper surface or plane as the main surface of the semiconductor substrate SB, as well as in the second direction intersecting the first direction within the upper surface as the main surface of the semiconductor substrate SB. That is, the semiconductor substrate SB has, over the upper surface as the main surface thereof, a pixel region in which the regions AR with pixels formed therein are arranged in the matrix.

Each of the regions AR is provided with a pixel serving as a light receiving section of the imaging element. Thus, the pixels are arranged in a matrix in the first direction within the upper surface as the main surface of the semiconductor substrate SB, as well as in the second direction intersecting the first direction within the upper surface as the main surface of the semiconductor substrate SB.

Note that the semiconductor substrate SB may have a peripheral circuit region (not shown) arranged along with the pixel region over the upper surface as the main surface of the semiconductor substrate SB. The peripheral circuit region includes not a light receiving section, but for example, a transistor for use in a switch or the like that can operate at high speed, a wiring layer thereover, and the like.

Then, the photodiodes PD including the respective pixels, the transfer transistors TX, and the amplification transistors are formed in the respective regions AR.

The p-type semiconductor layer PW with p-type impurities, such as boron (B), introduced thereinto is formed on the side of an upper surface of the semiconductor substrate SB across the regions AR. On the other hand, in each of the regions AR, the n-type semiconductor layer NW with n-type impurities, such as phosphorus (P) or arsenic (As), introduced thereinto is formed in an upper part of the p-type semiconductor layer PW. Thus, in each region AR, the p-type semiconductor layer PW is formed directly under the n-type semiconductor layer NW. The p-type semiconductor layer PW and the n-type semiconductor layer NW form a p-n junction to thereby configure the photodiode PD.

For example, the photodiode PDr is formed in the region ARr where the pixel for incidence of red (R) light is formed, at the upper surface as the main surface of the semiconductor substrate SB. The photodiode PDg is formed in the region ARg where the pixel for incidence of green (G) light is formed, at the upper surface as the main surface of the semiconductor substrate SB. The photodiode PDb is formed in the region ARb where the pixel for incidence of blue (B) light is formed, at the upper surface as the main surface of the semiconductor substrate SB.

The gate electrode GE made of, for example, a polysilicon film is formed over the upper surface of the semiconductor substrate SB via a gate insulating film GI made of, for example, a silicon oxide film. The sidewalls SW made of, for example, a silicon oxide film are formed over the side surfaces of each gate electrode GE. The gate electrode GE is agate electrode for the transfer transistor TX. On the other hand, the n-type semiconductor layer NW included in the photodiode PD also serves as the source region of the transfer transistor TX.

FIG. 3 omits the illustration of a drain region of the transfer transistor TX. The photodiode PD is coupled to a transistor, such as an amplification transistor for amplifying a signal output from the photodiode PD, via the transfer transistor TX. Here, FIG. 3 shows only the transfer transistor TX, and omits the illustration of an element isolation region or the like.

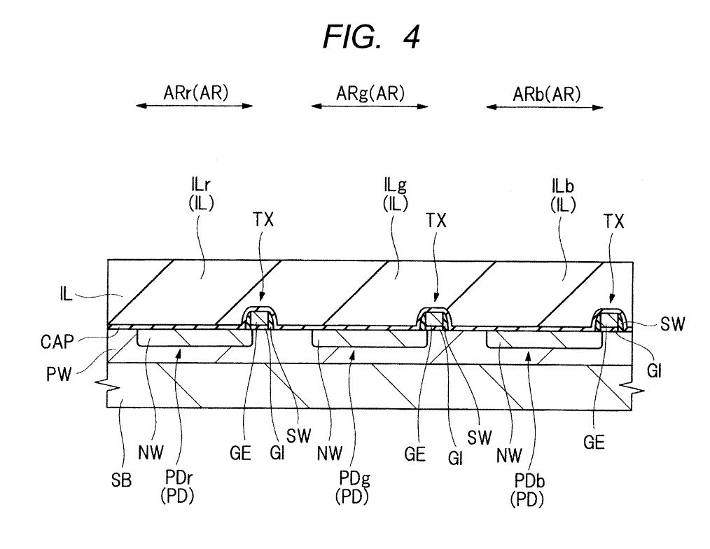

Then, the interlayer insulating film IL is formed (in step S12 of FIG. 2). In step S12, as shown in FIG. 4, the interlayer insulating film IL made of, e.g., a silicon oxide film is formed over the upper surface of the semiconductor substrate SB, for example, by a chemical vapor deposition (CVD) method so as to cover the semiconductor elements, including the photodiode PD and the transfer transistor TX, in each of the regions AR. Further, the upper surface of the interlayer insulating film IL is planarized by the CMP method or the like.

Apart of the interlayer insulating film IL located over the photodiode PDr in the region ARr is hereinafter referred to as the part ILr. Apart of the interlayer insulating film IL located over the photodiode PDg in the region ARg is hereinafter referred to as the part ILg. A part of the interlayer insulating film IL located over the photodiode PDb in the region ARb is hereinafter referred to as the part ILb.

That is, the part ILr is the interlayer insulating film IL positioned over the photodiode PDr in the region ARr. The part ILg is the interlayer insulating film IL positioned over the photodiode PDg in the region ARg. The part ILb is the interlayer insulating film IL positioned over the photodiode PDb in the region ARb.

The cap insulating film CAP made of, for example, a silicon nitride film may be formed over the upper surface of the photodiode PD, the upper surface of the gate electrode GE, and the surfaces of the sidewalls SW formed at the side surfaces of the gate electrode GE. In this case, the interlayer insulating film IL is formed over the photodiode PD and the transfer transistor TX via the cap insulating film CAP.

After forming the interlayer insulating film IL, contact holes (not shown) are formed to reach the semiconductor substrate SB while penetrating the interlayer insulating film IL. The metal film can be embedded in the respective contact holes to thereby form a plurality of contact plugs (not shown) made of the metal film embedded in the respective contact holes. In this case, the upper surfaces of the contact plugs and the upper surface of the interlayer insulating film IL are planarized by the CMP method or the like.

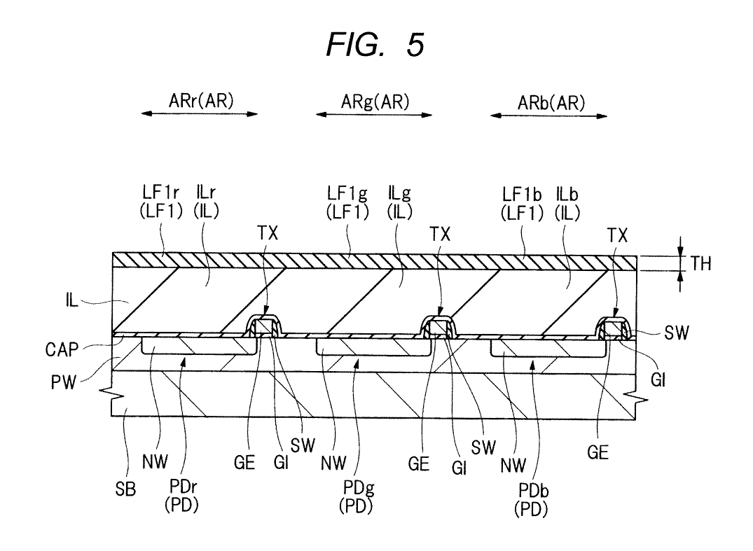

Then, the liner film LF1 is deposited (in step S13 of FIG. 2). In step S13, as shown in FIG. 5, the liner film LF1 made of an insulating film, such as a silicon carbonitride (SiCN) film, is deposited over the interlayer insulating film IL. The liner film LF1 is a protective film for protecting, for example, the interlayer insulating film IL. The thickness of the liner film LF1 at this time, that is, an initial thickness of the liner film LF1 is hereinafter referred to as the thickness TH.

A part of the liner film LF1 located above the part ILr of the interlayer insulating film IL in the region ARr is hereinafter referred to as a part LF1r. A part of the liner film LF1 located above the part ILg of the interlayer insulating film IL in the region ARg is hereinafter referred to as a part LF1g. A part of the liner film LF1 located above the part ILb of the interlayer insulating film IL in the region ARb is hereinafter referred to as a part LF1b.

That is, the part IF1r is a part of the liner film LF1 positioned above the photodiode PDr in the region ARr. The part IF1g is a part of the liner film LF1 positioned above the photodiode PDg in the region ARg. The part IF1b is a part of the liner film LF1 positioned above the photodiode PDb in the region ARb.

In step S13, when depositing the liner film LF1 made of, for example, SiCN film, the liner film LF1 can be deposited by the CVD method, preferably using tetra methyl silane (TMS) gas and ammonia (NH₃) gas as raw material gas. The CVD method for use can be, preferably, a high density plasma (HDP) CVD method.

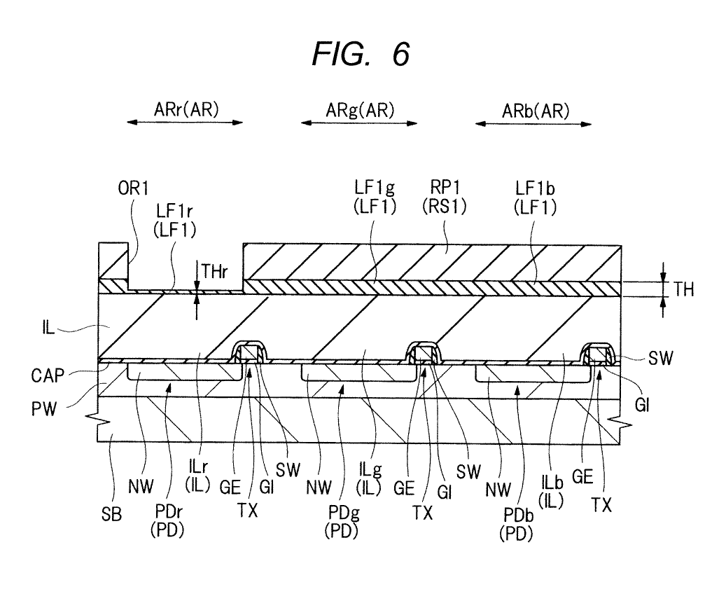

Then, the liner film LF1 is etched (in step S14 of FIG. 2) In step S14, first, as shown in FIG. 6, the liner film LF1 in the region ARr is etched by the photolithograph and etching such that the thickness THr of a part of the liner film LF1 positioned above the photodiode PDr is thinner than the initial thickness TH of the liner film LF1.

A resist film RS1 is formed over the liner film LF1 by applying a resist solution thereto, and the thus-formed resist film RS1 is exposed to and patterned by light, and then developed. In this way, in the region ARr, an opening OR1 is formed to reach the part of the linear film LF1 positioned above the photodiode PDr while penetrating the resist film RS1. As a result, a resist pattern RP1 made of the resist film RS1 is formed with the opening OR1 formed therein. The upper surface of the liner film LF1 is exposed at the bottom surface of the opening OR1. The liner film LF1 is covered with the resist film RS1 in the regions ARg and ARb, and between the adjacent regions ARr, ARg, and ARb.

Thereafter, the part of the liner film LF1 exposed at the bottom surface of the opening OR1 of the resist pattern RP1 is etched using the resist pattern RP1 as a mask. Thus, the thickness THr of the liner film LF1 positioned above the photodiode PDr, that is, the thickness THr of the part LF1r of the liner film LF1 is thinner than the initial thickness TH of the liner film LF1. For example, the liner film LF1 can be etched by dry etching using an etching gas. Etching gases for use preferably include carbon fluoride (fluorocarbon) gas, such as carbon tetra fluoride (CF₄) gas, or trifuluoromethane (CHF₃) gas, and gas containing fluorine, such as nitrogen trifluoride (NF₃) gas or sulfur hexafluoride (SF₆) gas. Among them, CF₄ gas or NF₃ gas is more preferably used.

Thereafter, the resist pattern RP1 is removed, for example, by ashing using oxygen plasma.

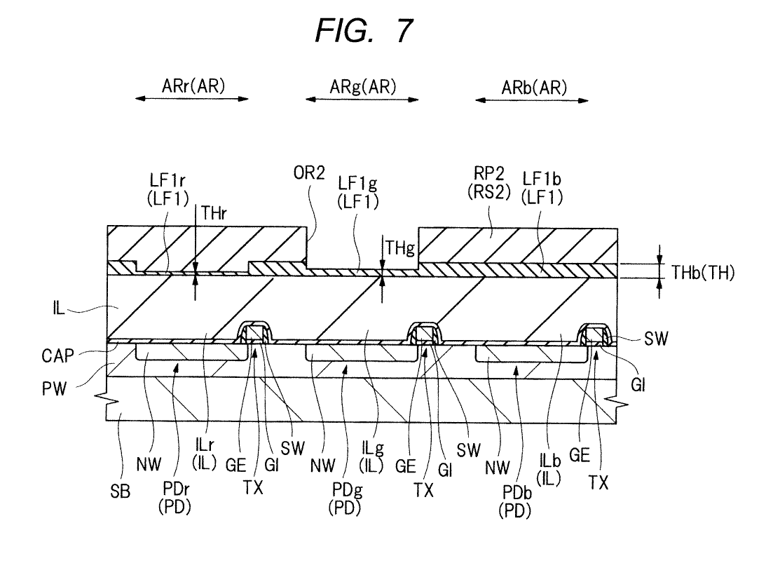

Next, in step S14, as shown in FIG. 7, the liner film LF1 in the region ARg is etched by the photolithograph and etching such that the thickness THg of a part of the liner film LF1 positioned above the photodiode PDg is thinner than the initial thickness TH of the liner film LF1. At this time, the liner film LF1 in the region ARg is etched by the photolithograph and etching such that the thickness THr of a part of the liner film LF1 positioned above the photodiode PDr is thinner than the thickness THg of the part of the liner film LF1 positioned above the photodiode PDg.

A resist film RS2 is formed over the liner film LF1 by applying a resist solution thereto, and the thus-formed resist film RS2 is exposed and patterned, and then developed. In this way, in the region ARg, an opening OR2 is formed to reach the linear film LF1 positioned above the photodiode PDg while penetrating the resist film RS2. As a result, a resist pattern RP2 made of the resist film RS2 is formed with the opening OR2 formed therein. The upper surface of the liner film LF1 is exposed at the bottom surface of the opening OR2. The liner film LF1 is covered with the resist film RS2 in the regions ARr and ARb, and between the adjacent regions ARr, ARg, and ARb.

Thereafter, the part of the liner film LF1 exposed at the bottom surface of the opening OR2 of the resist pattern RP2 is etched using the resist pattern RP2 as a mask. At this time, the etching is performed such that the thickness THg of the part of the liner film LF1 positioned above the photodiode PDg, that is, the thickness THg of the part LF1g of the liner film LF1 is thinner than the initial thickness TH of the liner film LF1, and thicker than the thickness THr of the part of the liner film LF1 positioned above the photodiode PDr. For example, the liner film LF1 can be etched by dry etching using an etching gas. The etching gas for use at this time can be the same as that used in etching the liner film LF1 in the region ARg.

Thereafter, the resist pattern RP2 is removed, for example, by ashing using oxygen plasma.

When the thickness of the part LF1b of the liner film LF1 obtained after the step S14 is a thickness THb, the thickness THb is equal to the thickness TH. Thus, the thickness THr is thinner than the thickness THg, and the thickness THg is thinner than the thickness THb. That is, when the wavelength of the light incident on the region ARr is longer than that of the light incident on the region ARg, preferably, the thickness THr of the part of the liner film LF1 positioned above the photodiode PDr is thinner than the thickness THg of the part of the liner film LF1 positioned above the photodiode PDg. When the wavelength of the light incident on the region ARg is longer than that of the light incident on the region ARb, preferably, the thickness THg of the part of the liner film LF1 positioned above the photodiode PDg is thinner than the thickness THb of the part of the liner film LF1 positioned above the photodiode PDb.

The etching of the liner film LF1 in the region ARr and the etching of the liner film LF1 in the region ARg may be performed in any order.

In an example shown in the present embodiment, the liner film LF1 in the region ARb is not etched. However, as long as the desired magnitude relationship among the thicknesses THr, THg, and THb of the liner film LF1 in the respective regions ARr, ARg, and ARb is satisfied, the liner film LF1 in the region ARb may be etched. In this case, the etching of the liner film LF1 in the region ARr, the etching of the liner film LF1 in the region ARg, and the etching of the liner film LF1 in the region ARb may be performed in any order.

Further, in the present embodiment, after depositing the liner film LF1, the liner film LF1 is etched such that the thickness THr is thinner than the thickness THg, and that the thickness THg is thinner than the thickness THb. However, instead of this, when depositing the liner film LF1, the liner film LF1 may be formed without any etching by depositing the liner film LF1 while varying the deposition time in each of the regions ARr, ARg, and ARb so as to make the thickness THr thinner than the thickness THg and to make the thickness THg thinner than the thickness THb.

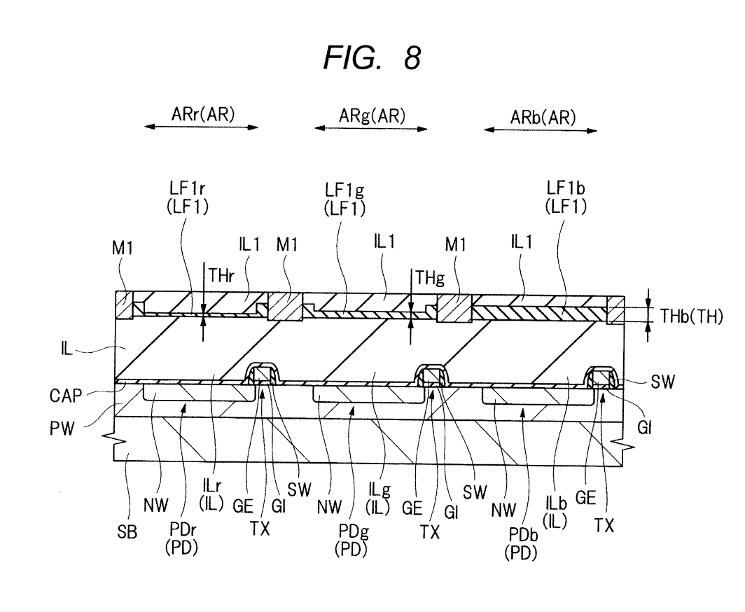

Next, the interlayer insulating film IL1 and the wiring M1 are formed (in step S15). As shown in FIG. 8, in step S15, the interlayer insulating film IL1 made of a silicon oxide (SiO₂) film is formed over the liner film LF1 by the CVD method using, for example, tetraethyl orthosilicate (TEOS) gas as a raw material gas. In this way, the interlayer insulating film IL1 is formed over the liner film LF1 in the regions ARr, ARg, and ARb.

Then, the wirings M1 are formed to be embedded in wiring trenches located in the upper surface of the interlayer insulating film IL1 using the so-called single Damascene method.

As shown in FIG. 8, first, the interlayer insulating film IL1 and the liner film LF1 are patterned by the photolithography and etching to thereby forma plurality of wiring trenches penetrating the interlayer insulating film IL1 and liner film LF1 between the adjacent regions ARr, ARg, and ARb.

When patterning the interlayer insulating film IL1 and liner film LF1, the interlayer insulating film IL1 and liner film LF1 can be etched by dry etching using gas containing, for example, carbon fluoride (fluorocarbon) gas as an etching gas.

Thereafter, as shown in FIG. 8, for example, a copper (Cu) film is embedded in each of the wiring trenches to thereby form the wiring M1 in each wiring trench between the adjacent regions ARr, ARg, and ARb. The wiring M1 is electrically coupled to the semiconductor element, such as the photodiode PD or transfer transistor TX, formed over the upper surface of the semiconductor substrate SB, via the contact plug.

The liner film LF1, the interlayer insulating film IL1, and the wiring M1 form the first wiring layer.

The wiring M1 is formed in an area between the respective regions AR, which can prevent or suppress the incident light from being blocked by the wiring M1 when the light enters the photodiode PD formed in each of the regions AR. The respective upper surfaces of the wiring M1 and the interlayer insulating film IL1 are planarized by the CMP method or the like.

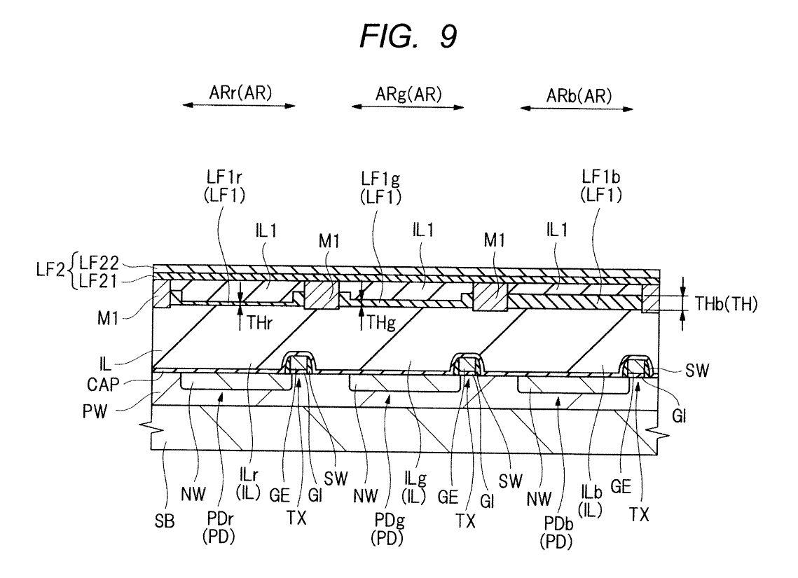

Then, the liner film LF2 is formed (in step S16 of FIG. 2). In step S16, as shown in FIG. 9, the liner film LF2 is formed over the interlayer insulating film IL1 and the wirings M1. The liner film LF2 is the laminated insulating film including the insulating film LF21 formed of, for example, a silicon carbonitride (SiCN) film, and the insulating film LF22 formed of, for example, an oxygen-containing silicon carbide (SiCO) film. In this way, the liner film LF2 is formed over the interlayer insulating film IL1 and wirings M1 in the regions ARr, ARg, and ARb. The liner film LF2 serves as a protective film for protecting the interlayer insulating film IL2. Alternatively, the liner film LF2 serves as a diffusion preventing film for preventing the diffusion of material included in the wiring M1, for example, copper (Cu).

In step S16, first, an insulating film LF21 made of, for example, a SiCN film is formed. At this time, like step S13, the insulating film LF21 can be preferably formed by the CVD method using TMS gas and ammonia (NH₃) gas as raw material gas.

Subsequently, an insulating film LF22 made of, for example, a SiCO film is formed. At this time, the insulating film LF22 can be formed by the CVD method, for example, TMS gas as a raw material gas. The SiCO film is formed of a silicon carbide (SiC) film as a principal component coupled to oxygen (O).

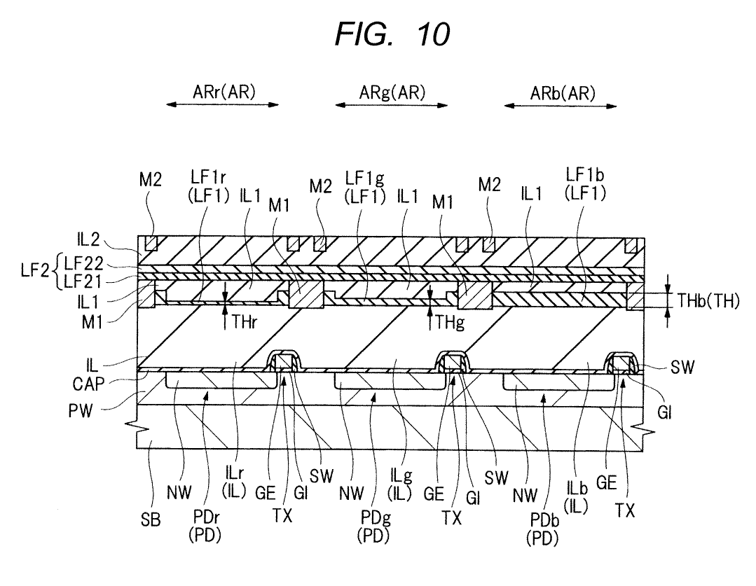

Next, the interlayer insulating film IL2 and the wiring M2 are formed (in step S17). As shown in FIG. 10, in step S17, the interlayer insulating film IL2 made of a carbon-contained silicon oxide (SiOC) film is formed over the liner film LF2 by the CVD method using trimethylsilane (SiH(CH₃)₃) gas and oxygen (O₂) gas as raw material gas. In this way, the interlayer insulating film IL2 is formed over the liner film LF2 in the regions ARr, ARg, and ARb.

The SiOC film is formed of the silicon oxide (SiO) film as a principal component containing carbon (C). Thus, a carbon content of the SiOC film with respect to an oxygen content thereof is smaller than a carbon content of the SiCO film with respect to an oxygen content thereof.

Then, the wirings M2 embedded in the wiring trenches in the upper surface of the interlayer insulating film IL2, and vias (not shown) located directly under the wirings M2 for coupling the wirings M2 and M1 are formed by the so-called Dual Damascene method.

First, as shown in FIG. 10, the interlayer insulating film IL2 is patterned using the photolithography and etching. Thus, a plurality of wiring trenches are formed at the upper surface of the interlayer insulating film IL2 between the adjacent regions ARr, ARg, and ARb, and a plurality of via holes (not shown) penetrating the interlayer insulating film IL2 are formed at the bottom surfaces of the wiring trenches.

In the step of patterning the interlayer insulating film IL2, the interlayer insulating film IL2 can be etched, for example, by dry etching using gas containing carbon fluoride (fluorocarbon) gas as an etching gas.

Thereafter, as shown in FIG. 10, for example, the copper (Cu) film is embedded in each of the wiring trenches and the vias to thereby form the wiring M2 for each wiring trench and the via for each via hole between the adjacent regions ARr, ARg, and ARb. The wiring M2 is electrically coupled to the wiring M1 via the via.

The liner film LF2, the interlayer insulating film IL2, the wiring M2, and the above-mentioned vias (not shown) form the second wiring layer.

The wiring M2 is formed in an area between the respective regions AR, which can prevent or suppress the incident light from being blocked by the wiring M2 when the light enters the photodiode PD formed in each of the regions AR. The respective upper surfaces of the wiring M2 and the interlayer insulating film IL2 are planarized by the CMP method or the like.

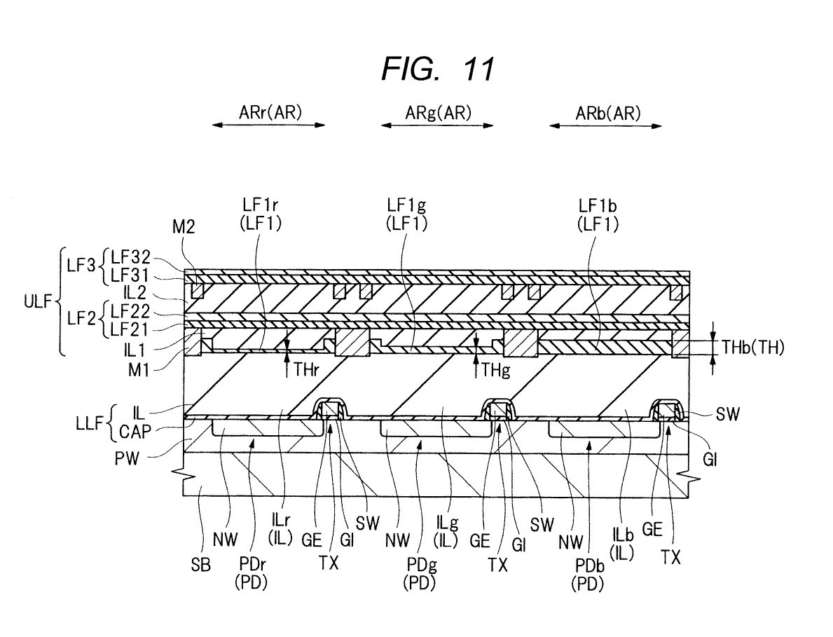

Then, the liner film LF3 is deposited (in step S18 of FIG. 2). Like step S17, in step S18, as shown in FIG. 11, the liner film LF3 is formed over the interlayer insulating film IL2, for example, by the CVD method. The liner film LF3 is the laminated insulating film including an insulating film LF31 formed of, for example, a silicon carbonitride (SiCN) film, and an insulating film LF32 formed of, for example, an oxygen-containing silicon carbide (SiCO) film. In this way, the liner film LF3 is formed over the interlayer insulating film IL2 and the wirings M2 in the respective regions ARr, ARg, and ARb. The liner film LF3 serves as a protective film for protecting the interlayer insulating film IL2. Alternatively, the liner film LF3 serves as a diffusion preventing film for preventing the diffusion of material included in the wiring M2, for example, copper (Cu).

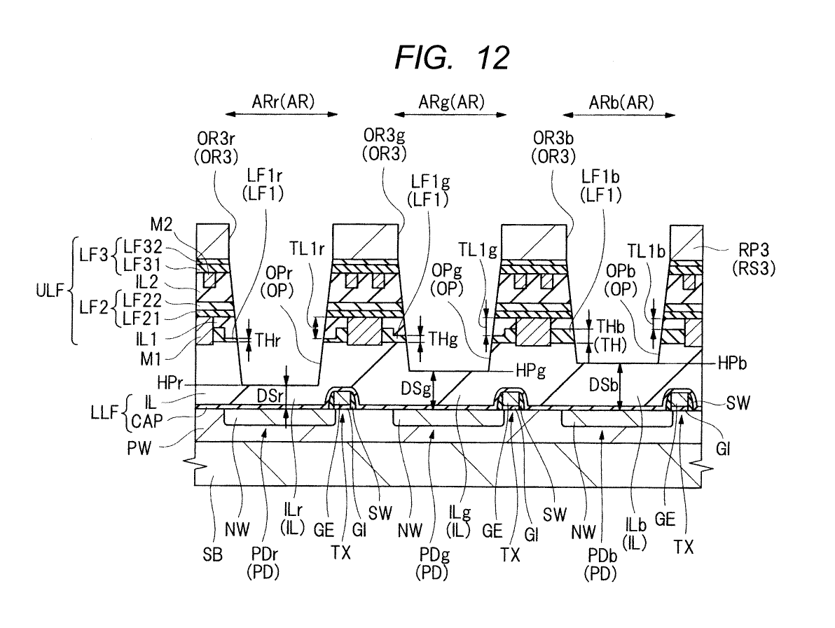

Then, the openings OP are formed (in step S19 of FIG. 2). In step S19, as shown in FIG. 12, in the regions AR, the liner film LF3, the interlayer insulating film IL2, the liner film LF2, the interlayer insulating film IL1, the liner film LF1, and the interlayer insulating film IL are patterned by the photography and etching. Thus, the openings OP are formed to reach the midway point of the interlayer insulating film IL in the thickness direction while penetrating the liner film LF3, the interlayer insulating film IL2, the liner film LF2, the interlayer insulating film IL1, and the liner film LF1.

Specifically, in the region ARr, the opening OPr is formed to reach the midway point of the interlayer insulating film IL in the thickness direction while penetrating the liner film LF3, the interlayer insulating film IL2, the liner film LF2, the interlayer insulating film IL1, and the liner film LF1. In the region ARg, the opening OPg is formed to reach the midway point of the interlayer insulating film IL in the thickness direction while penetrating the liner film LF3, the interlayer insulating film IL2, the liner film LF2, the interlayer insulating film IL1, and the liner film LF1. In the region ARb, the opening OPb is formed to reach the midway point of the interlayer insulating film IL in the thickness direction while penetrating the liner film LF3, the interlayer insulating film IL2, the liner film LF2, the interlayer insulating film IL1, and the liner film LF1.

In step S19, first, a resist film RS3 is formed over the liner film LF3 by applying a resist solution thereto, and the thus-formed resist film RS3 is exposed and patterned by light, and developed. Openings OR3 are formed to reach the part of the liner film LF3 positioned above the photodiode PD through the resist film RS3. Thus, a resist pattern RP3 is formed of the resist film RS3 with the openings OR3 formed therein.

For example, in the region ARr, an opening OR3r is formed to reach the part of the liner film LF3 positioned above the photodiode PDr through the resist film RS3. In the region ARg, an opening OR3g is formed to reach the part of the liner film LF3 positioned above the photodiode PDg through the resist film RS3. In the region ARb, an opening OR3b is formed to reach the part of the liner film LF3 positioned above the photodiode PDb through the resist film RS3. Thus, the resist pattern RP3 made of the resist film RS3 with the openings OR3r, OR3g, and OR3b is formed.

The upper surface of the liner film LF3 is exposed in the bottom surface of each of the openings OR3r, OR3g, and OR3b. The liner film LF3 is covered by the resist film RS3 between the adjacent regions ARr, ARg, and ARb.

Thereafter, the part of the liner film LF3 exposed at the bottom of the opening OR3 of the resist pattern RP3, and the part of the interlayer insulating film IL2 under the liner film LF3 are etched using the resist pattern RP3 as the mask. Thus, the opening is formed to reach the upper surface of the part of the liner film LF2 positioned above the photodiode PD while penetrating the parts of the liner film LF3 and the interlayer insulating film IL2 positioned above the photodiode PD. For example, the liner film LF3 and the interlayer insulating film IL2 can be etched by dry etching using etching gas. Etching gases for use preferably include carbon fluoride (fluorocarbon) gas, such as carbon tetrafluoride (CF₄) gas, or trifuluoromethane (CHF₃) gas, and gas containing fluorine, such as nitrogen trifluoride (NF₃) gas or sulfur hexafluoride (SF₆) gas. Among them, CF₄ gas or NF₃ gas is more preferably used.

For example, in the region ARr, the part of the liner film LF3 exposed at the bottom surface of the opening OR3r, and the part of the interlayer insulating film IL2 positioned thereunder are etched. In this way, the opening is formed to reach the upper surface of the part of the liner film LF2 positioned above the photodiode PDr, while penetrating the parts of the liner film LF3 and interlayer insulating film IL2 positioned above the photodiode PDr.

In the region ARg, the part of the liner film LF3 exposed at the bottom surface of the opening OR3g, and the part of the interlayer insulating film IL2 positioned thereunder are etched. In this way, the opening is formed to reach the upper surface of the part of the liner film LF2 positioned above the photodiode PDg, while penetrating the parts of the liner film LF3 and interlayer insulating film IL2 positioned above the photodiode PDg.

In the region ARb, the part of the liner film LF3 exposed at the bottom surface of the opening OR3b, and the part of the interlayer insulating film IL2 positioned thereunder are etched. In this way, the opening is formed to reach the upper surface of the part of the liner film LF2 positioned above the photodiode PDb, while penetrating the parts of the liner film LF3 and interlayer insulating film IL2 positioned above the photodiode PDb.

In the etching, the liner film LF2 comprised of the insulating film LF21 made of, e.g., a SiCN film, and the insulating film LF22 made of, e.g., a SiCO film serves as an etching stopper film when etching the interlayer insulating film IL2 made of, e.g., a SiOC film. That is, an etching selectivity, which is a ratio of an etching rate of the interlayer insulating film IL2 to that of the liner film LF2, is larger than 1. Thus, once the opening reaches the upper surface of the liner film LF2 through the interlayer insulating film IL2, the etching can be stopped with high accuracy.

Thereafter, apart of the liner film LF2 exposed at the bottom surface of the opening, and the interlayer insulating film IL1, liner film LF1, and interlayer insulating film IL located under the part of the liner film LF2 are etched. Thus, the opening OP is formed to reach the midway point of the part of the interlayer insulating film IL in the thickness direction above the photodiode PD while penetrating the part of the liner film LF2 above the photodiode PD, the interlayer insulating film IL1, and the liner film LF1. For example, the liner film LF2, the interlayer insulating film IL1, and the liner film LF1 can be etched by dry etching using etching gas. Etching gases for use preferably include carbon fluoride (fluorocarbon) gas, such as carbon tetrafluoride (CF₄) gas, or trifuluoromethane (CHF₃) gas, and gas containing fluorine, such as nitrogen trifluoride (NF₃) gas or sulfur hexafluoride (SF₆) gas. Among them, CF₄ gas or NF₃ gas is more preferably used.

For example, in the region ARr, the part of the liner film LF2 exposed at the bottom surface of the opening, and the parts of the interlayer insulating film IL1, liner film LF1, and interlayer insulating film IL positioned thereunder are etched. Thus, in the region ARr, the opening OPr is formed to reach the midway point of the interlayer insulating film IL in the thickness direction above the photodiode PDr while penetrating the parts of the liner film LF2, the interlayer insulating film IL1, and the liner film LF1 positioned above the photodiode PDr.

In the region ARg, the part of the liner film LF2 exposed at the bottom surface of the opening, and the parts of the interlayer insulating film IL1, liner film LF1, and interlayer insulating film IL positioned thereunder are etched. Thus, in the region ARg, the opening OPg is formed to reach the midway point of the interlayer insulating film IL in the thickness direction above the photodiode PDg while penetrating the parts of the liner film LF2, the interlayer insulating film IL1, and the liner film LF1 positioned above the photodiode PDg.

In the region ARb, the part of the liner film LF2 exposed at the bottom surface of the opening, and the parts of the interlayer insulating film IL1, liner film LF1, and interlayer insulating film IL positioned thereunder are etched. Thus, in the region ARb, the opening OPb is formed to reach the midway point of the interlayer insulating film IL in the thickness direction above the photodiode PDb while penetrating the parts of the liner film LF2, the interlayer insulating film IL1, and the liner film LF1 positioned above the photodiode PDb.

Etching of the respective layers from the liner film LF3 to the interlayer insulating film IL can be continuously performed in the same etching step. Alternatively, as mentioned above, for example, the etching is temporarily stopped at the upper surface of the liner film LF2. In this way, the etching can also be divided into a plurality of etching steps.

The thickness THr of the part of the liner film LF1 positioned above the photodiode PDr, the thickness THg of the part of the liner film LF1 positioned above the photodiode PDg, and the thickness THb of the part of the liner film LF1 positioned above the photodiode PDb differ from one another. When etching the interlayer insulating film IL1 made of, e.g., a silicon oxide film, the liner film LF1 made of, e.g., a SiCN film serves as an etching stopper film. Among the respective regions ARr, ARg, and ARb, the time required for etching the liner film LF1, that is, the time required for the opening OP to penetrate the liner film LF1 from its upper surface to its lower surface can differ from each other. When the height position HPr is the height position of the bottom surface of the opening OPr, the height position HPg is the height position of the bottom surface of the opening OPg, and the height position HPb is the height position of the bottom surface of the opening OPb, the height positions HPr, HPg, and HPb can differ from one another.

When the wavelength of the light incident on the region ARr is longer than that of the light incident on the region ARg, the thickness THr of the part of the liner film LF1 positioned above the photodiode PDr in the region ARr is preferably thinner than the thickness THg of the part of the liner film LF1 positioned above the photodiode PDg in the region ARg. When the wavelength of the light incident on the region ARg is longer than that of the light incident on the region ARb, the thickness THg of the part of the liner film LF1 positioned above the photodiode PDg in the region ARg is preferably thinner than the thickness THb of the part of the liner film LF1 positioned above the photodiode PDb in the region ARb.

Here, a time for etching the part of the liner film LF1 positioned above the photodiode PDr in the region ARr, that is, a time required for the opening OPr to penetrate the liner film LF1 from an upper surface to a lower surface thereof is defined as a time M1r. In the region ARg, a time for etching the part of the liner film LF1 positioned above the photodiode PDg, that is, a time required for the opening OPg to penetrate the liner film LF1 from the upper surface to the lower surface thereof is defined as a time M1g. In the region ARb, a time for etching the part of the liner film LF1 positioned above the photodiode PDb, that is, a time for the opening OPb to penetrate the liner film LF1 from the upper surface to the lower surface thereof is defined as a time M1b.

On the other hand, in the region ARr, a time for etching the part of the interlayer insulating film IL positioned above the photodiode PDr is defined as a time M2r. In the region ARg, a time for etching the part of the interlayer insulating film IL positioned above the photodiode PDg is defined as a time M2g. In the region ARb, a time for etching the part of the interlayer insulating film IL positioned above the photodiode PDb is defined as a time M2b.

In this case, the time M1r is shorter than the time M1g, and the time M1g is shorter than the time M1b.

Assume that, for example, the thickness of the interlayer insulating film IL1 is equal among the regions ARr, ARg, and ARb without planarizing the upper surface of the interlayer insulating film IL1. In this case, when the openings OPr, OPg and OPb are simultaneously formed, the total of the times M1r and time M2r, the total of the times M1g and time M2g, and the total of the times M1b and M2b are equal to one another. Thus, the time M2r is longer than the time M2g, and the time M2g is longer than the time M2b. Thus, as shown in FIG. 12, the height position HPr of the bottom surface of the opening OPr can be lower than the height position HPg of the bottom surface of the opening OPg, and the height position HPg of the bottom surface of the opening OPg can be lower than the height position HPb of the bottom surface of the opening OPb.

On the other hand, assume that the upper surface of the interlayer insulating film IL1 is planarized. In this case, the thickness TL1r of the part of the interlayer insulating film IL1 positioned above the photodiode PDr in the region ARr is thicker than the thickness TL1g of the part of the interlayer insulating film IL1 positioned above the photodiode PDg in the region ARg. The thickness TL1g of the part of the interlayer insulating film IL1 positioned above the photodiode PDg in the region ARg is preferably thicker than the thickness TL1b of the part of the interlayer insulating film IL1 positioned above the photodiode PDb in the region ARb.

Here, in the region ARr, a time for etching the part of the interlayer insulating film IL1 positioned above the photodiode PDr is defined as the time M0r. In the region ARg, a time for etching the part of the interlayer insulating film IL1 positioned above the photodiode PDg is defined as the time M0g. In the region ARb, a time for etching the part of the interlayer insulating film IL1 positioned above the photodiode PDb is defined as a time M0b. At this time, the time M0r is longer than the time M0g, and the time M0g is longer than the time M0b.

In this case, when simultaneously forming the openings OPr, OPg, and OPb, the total of the times M0r, M1r, and M2r, the total of the times M0g, M1g, and M2g, and the total of the times M0b, M1b, and M2b are equal to one another.

In the etching, an etching selectivity, which is a ratio of an etching rate of the interlayer insulating film IL1 made of, e.g., a silicon oxide film, to that of the liner film LF1 made of, e.g., a SiCN film, is larger than 1. As a result, a difference between the times M0r and M0g is smaller than that between the times M1g and M1r, so that the time M2r is longer than the time M2g. Therefore, also when the thickness TL1r is larger than the thickness TL1g, and the thickness TL1g is larger than the thickness TL1b, as shown in FIG. 12, the height position HPr of the bottom surface of the opening OPr can be lower than the height position HPg of the bottom surface of the opening OPg, and the height position HPg of the opening OPg can be lower than the height position HPb of the bottom surface of the opening OPb.

In the present embodiment, the formation of the opening OPg and the opening OPb when forming the opening OPr has been described. That is, the simultaneous formation of the openings OPr, OPg, and OPb has been described. When forming the respective openings OPr, OPg, and OPb, for example, the total time for etching the respective layers including the interlayer insulating film IL1, the liner film LF1, and the interlayer insulating film IL should be set equal for each opening. However, the respective openings OPr, OPg, and OPb may not be formed simultaneously.

Thereafter, the resist pattern RP3 is removed by ashing, for example, oxygen plasma.

The regions ARr, ARg, and ARb are adjacent to each other. At this time, the wiring layer is formed of a plurality of insulating layers positioned between the openings OPr and OPg, namely, the liner film LF1, the interlayer insulating film IL1, the liner film LF2, the interlayer insulating film IL2, the liner film LF3, the wiring M1, and the wiring M2 formed inside the interlayer insulating film IL2. Further, the wiring layer is formed of a plurality of insulating layers positioned between the openings OPg and OPb, namely, the liner film LF1, the interlayer insulating film IL1, the liner film LF2, the interlayer insulating film IL2, the liner film LF3, the wiring M1, and the wiring M2 formed in the interlayer insulating film IL2.

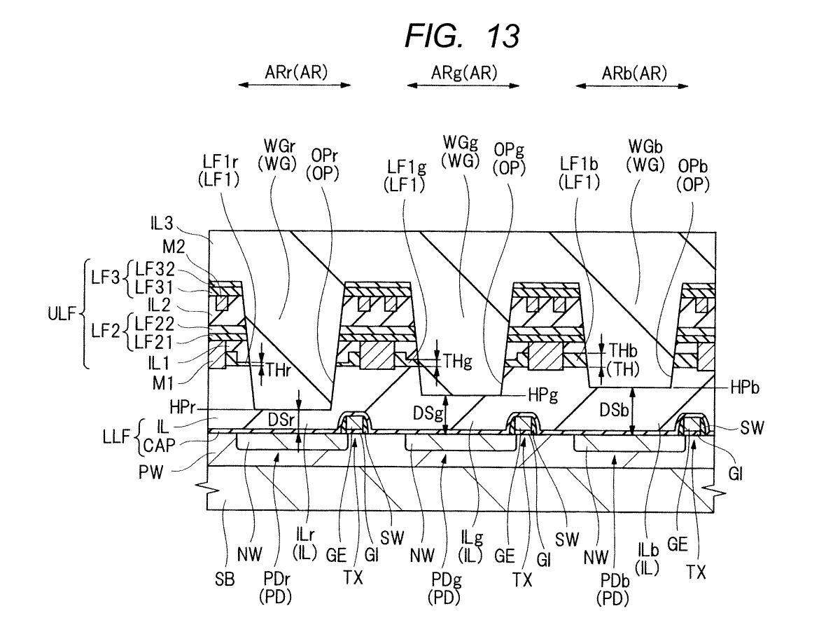

Then, the optical waveguides WG are formed (in step S20 of FIG. 2). In step S20, as shown in FIG. 13, the insulating film IL3 made of, e.g., a silicon nitride film is formed over the liner film LF3 including the inside of the opening OP, e.g., by the CVD method, so that the insulating film IL3 is embedded in the opening OP. Thus, in the region AR, the optical waveguide WG for guiding the incident light to the photodiode PD is formed above the photodiode PD. The optical waveguide WG is formed of the insulating film IL3 embedded in each opening OP.

Specifically, in the region ARr, an optical waveguide WGr for guiding the red (R) incident light to the photodiode PDr is formed above the photodiode PDr. The optical waveguide WGr is formed of the insulating film IL3 embedded in the opening OPr. In the region ARg, an optical waveguide WGg for guiding the green (G) incident light to the photodiode PDg is formed above the photodiode PDg. The optical waveguide WGg is formed of the insulating film IL3 embedded in the opening OPg. In the region ARb, an optical waveguide WGb for guiding the blue (B) incident light to the photodiode PDb is formed above the photodiode PDb. The optical waveguide WGb is formed of the insulating film IL3 embedded in the opening OPb.

A refractive index of the optical waveguide WG made of, e.g., a silicon nitride film is relatively large, for example, about 1.97. Thus, a refractive index of the optical waveguide WG can be higher than an average refractive index of the wiring layer around the optical waveguide WG, which can guide the incident light on the optical waveguide WG to the photodiode PD via the microlens ML and the color filter CF without attenuating the light so much.

In the region ARr, a distance from the lower surface of the optical waveguide WGr to the upper surface of the photodiode PDr is defined as a distance DSr. In the region ARg, a distance from the lower surface of the optical waveguide WGg to the upper surface of the photodiode PDg is defined as a distance DSg. In the region ARb, a distance from the lower surface of the optical waveguide WGb to the upper surface of the photodiode PDb is defined as a distance DSb.

A diameter of a lower surface of the optical waveguide WG is defined as a diameter DM1, and a diameter of a region of the upper surface of the photodiode PD on which light emitted from the lower surface of the optical waveguide WG is incident is defined as a diameter DM2. For example, the efficiency of incidence of the light with a wavelength λ on the photodiode PD is defined as a ratio of the diameter DM1 to the diameter DM2. At this time, in order to equalize the efficiencies of the pixels for detecting the lights in red (R), green (G), and blue (B), the distance from the lower surface of the optical waveguide WG to the upper surface of the photodiode PD is preferably increased in the order of red (R), green (G), and blue (B), that is, with decreasing wavelength λ. This is based on the fact that a diffraction state of the light differs depending on the wavelength λ thereof.

Next, a film made of, for example, a silicon oxide film is formed over the optical waveguide WG by the CVD method, and patterned using the photolithography and etching. Thus, the barrier wall BW made of, for example, a silicon oxide film is formed over the light waveguide WG between the adjacent regions ARr, ARg, and ARb.

Then, the color filter CF is formed between the adjacent barrier walls BW. Thus, the color filter CF is made of a film colored in each of colors, for example, red (R), green (G), and blue (B).

Specifically, in the region ARr, the red color filter CFr is formed between the adjacent barrier walls BW. In the region ARg, the green color filter CFg is formed between the adjacent barrier walls BW. In the region ARb, the blue color filter CFb is formed between the adjacent barrier walls BW. In this way, the semiconductor device of the present embodiment shown in FIG. 1 is completed.

After forming the color filters CF, the microlens ML may be formed over the corresponding color filter CF in each of the regions ARr, ARg, and ARb. The microlens ML is a convex lens having its upper surface curved, and made of a film that can transmit light therethrough. The microlens ML collects the light applied from the main surface side or upper surface side of the semiconductor substrate SB to the regions AR with the pixels formed thereat, into the photodiodes PD via the color filters CF, optical waveguides WG, and interlayer insulating films IL.

For example, after a film is formed over the barrier wall BW and color filter CF, the formed film can be heated and partly melt to round an upper surface of the film, thereby forming the microlens ML.

### <Amount of Use of Resist, and Ashing Damage>

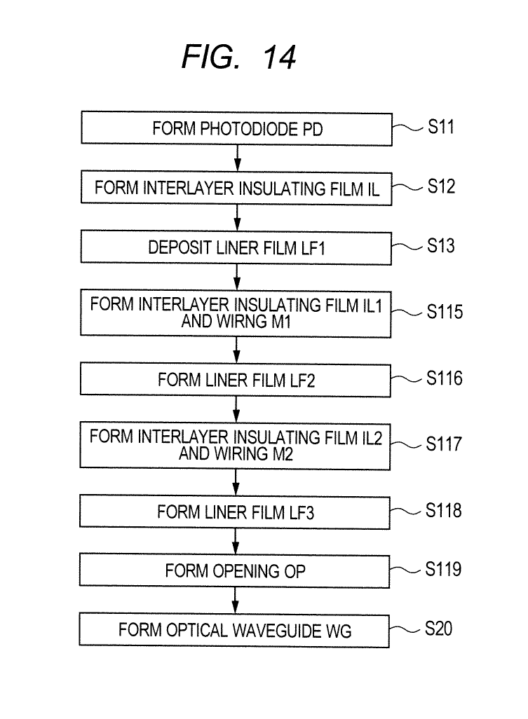

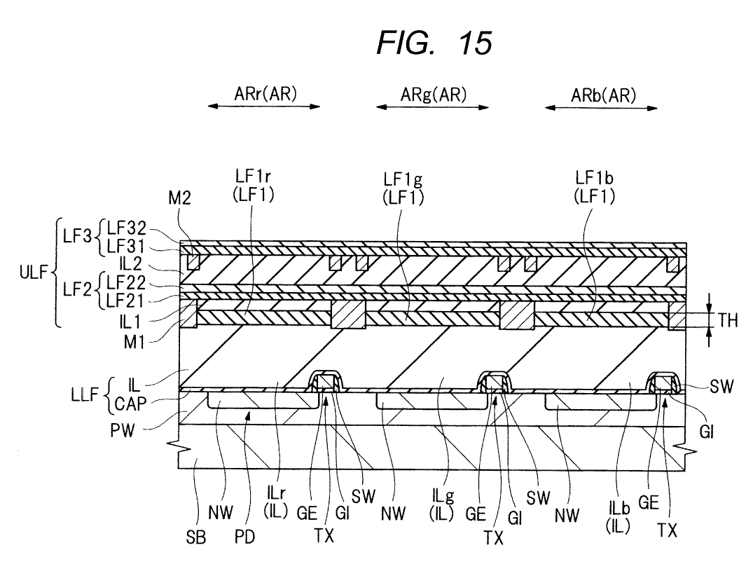

Now, the amount of use of resist and ashing damage when forming the openings will be described by comparison with a manufacturing method of a semiconductor device in a comparative example. FIG. 14 is a manufacturing process flowchart showing parts of manufacturing steps of the semiconductor device in the comparative example. FIGS. 15 to 18 are cross-sectional views of main parts of other manufacturing steps of the semiconductor device in the comparative example.

As shown in FIG. 14, in the manufacturing procedure of the semiconductor device in the comparative example, the liner film LF1 is formed by performing the same processes as those in steps S11 to S13 shown in FIG. 2 in the manufacturing procedure of the semiconductor device of the present embodiment. Then, without performing step S14 of FIG. 2, the same processes as those in steps S15 to S18 of FIG. 2 are also performed (in steps S115 to S118 of FIG. 14). That is, in the comparative example, as shown in FIG. 15, the thicknesses of the liner films LF1 are the same in the respective regions ARr, ARg, and ARb. The interlayer insulating film IL1, the wiring M1, the liner film LF2, the interlayer insulating film IL2, the wiring M2, and the liner film LF3 are formed over the liner film LF1 keeping the thickness TH.

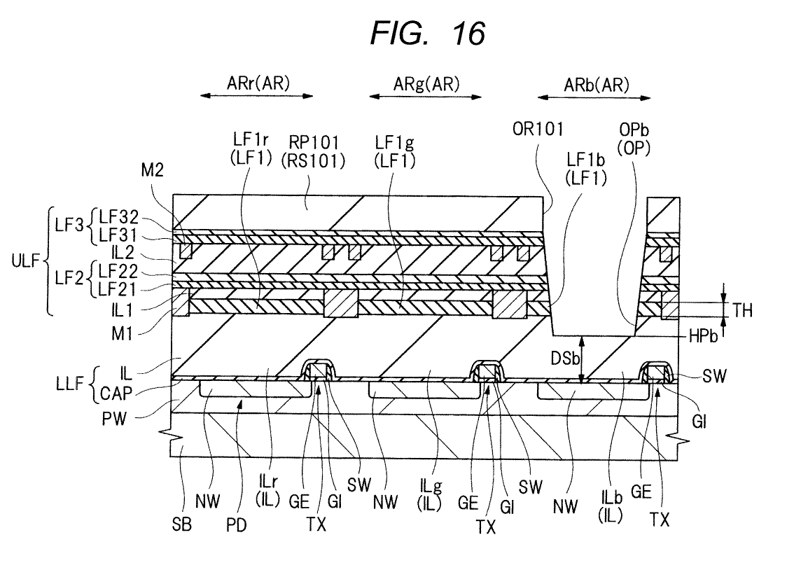

Then, openings OPr, OPg, and OPb are formed (in step S119 of FIG. 14). In step S119, first, as shown in FIG. 16, in the region ARb, the liner film LF3, interlayer insulating film IL2, liner film LF2, interlayer insulating film IL1, liner film LF1, and interlayer insulating film IL are patterned by using the photolithography and etching.

First, a resist film RS101 is formed over the liner film LF3 by applying a resist solution thereto, and the thus-formed resist film RS101 is exposed and patterned by light and developed. Thus, in the region ARb, the opening OR101 is formed to reach the part of the liner film LF3 positioned above the photodiode PDb through the resist film RS101. Then, a resist pattern RP101 made of the resist film RS101 with the opening OR101 formed therein is formed.

Thereafter, the dry etching is performed using the resist pattern RP101 as a mask. In this way, the opening OPb is formed in the region ARb to reach the midway point of the part of the interlayer insulating film IL over the photodiode PDb in the thickness direction, while penetrating the liner film LF3, the interlayer insulating film IL2, the liner film LF2, the interlayer insulating film IL1, and the liner film LF1. Thereafter, the resist pattern RP101 is removed by ashing, for example, using oxygen plasma.

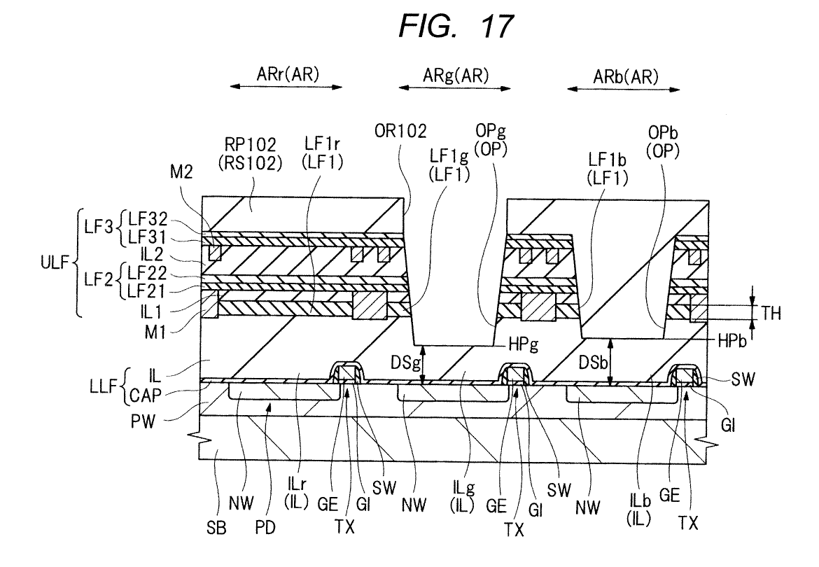

Next, in step S119, as shown in FIG. 17, in the region ARg, the liner film LF3, interlayer insulating film IL2, liner film LF2, interlayer insulating film IL1, liner film LF1, and interlayer insulating film IL are patterned by using the photolithography and etching.

First, a resist film RS102 is formed over the liner film LF3 by applying a resist solution thereto, and the thus-formed resist film RS102 is exposed and patterned by light and developed. Thus, in the region ARg, an opening OR102 is formed to reach the part of the liner film LF3 positioned above the photodiode PDg through the resist film RS102. Then, a resist pattern RP102 made of the resist film RS102 with the opening OR102 formed therein is formed.

Thereafter, the dry etching is performed using the resist pattern RP102 as a mask. In this way, the opening OPg is formed in the region ARg to reach the midway point of the part of the interlayer insulating film IL in the thickness direction above the photodiode PDg, while penetrating the liner film LF3, the interlayer insulating film IL2, the liner film LF2, the interlayer insulating film IL1, and the liner film LF1. Thereafter, the resist pattern RP102 is removed by ashing, for example, using oxygen plasma.

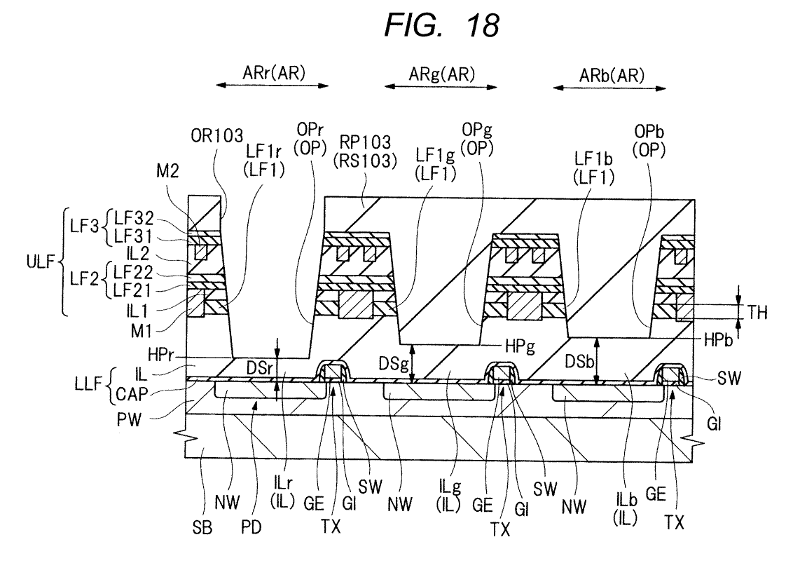

In step S119, as shown in FIG. 18, in the region ARr, the liner film LF3, interlayer insulating film IL2, liner film LF2, interlayer insulating film IL1, liner film LF1, and interlayer insulating film IL are patterned by using the photolithography and etching.

First, a resist film RS103 is formed over the liner film LF3 by applying a resist solution thereto, and the thus-formed resist film RS103 is exposed and patterned by light, and developed. Thus, in the region ARr, an opening OR103 is formed to reach the part of the liner film LF3 positioned above the photodiode PDr through the resist film RS103. Then, a resist pattern RP103 made of the resist film RS103 with the opening OR103 formed therein is formed.

Thereafter, the dry etching is performed using the resist pattern RP103 as a mask. In this way, the opening OPr is formed in the region ARr to reach the midway point of the part of the interlayer insulating film IL in the thickness direction above the photodiode PDr, while penetrating the liner film LF3, the interlayer insulating film IL2, the liner film LF2, the interlayer insulating film IL1, and the liner film LF1. Thereafter, the resist pattern RP103 is removed by ashing, for example, using oxygen plasma.

In the comparative example, then, the same processes as those in step S20 and other steps following step S20 of FIG. 2 in the manufacturing procedure of the semiconductor device in the present embodiment are performed to manufacture an imaging element as the semiconductor device.

In the comparative example, for example, the etching time is varied among the respective regions ARr, ARg, and ARb, whereby the height position HPr of the bottom surface of the opening OPr, the height position HPg of the bottom surface of the opening OPg, and the height position of the bottom surface of the opening OPb differ from one another. And, in the respective regions ARr, ARg, and ARb, the distances DSr, DRg, and DSb from the lower surface of the optical waveguide WG to the upper surface of the photodiode PD also differ from one another to optimize the length or distance so as to maximize the efficiency of the pixel for detecting each of different colors.

In the comparative example, however, in step S119, the etching process for the liner film LF3, the interlayer insulating film IL2, the liner film LF2, the interlayer insulating film IL1, the liner film LF1, and the interlayer insulating film IL has to be repeatedly performed three times for the respective regions ARr, ARg, and ARb. Thus, the number of the etching processes for the layers from the liner film LF3 to the interlayer insulating film IL is increased. This leads to a complicated manufacturing procedure of the semiconductor device, resulting in an increase in manufacturing cost.

When forming the resist film over the semiconductor substrate by applying the resist solution thereto, for example, the resist solution is supplied using a nozzle toward the center of rotation on the upper surface of the rotating semiconductor substrate, and then the supplied resist solution expands on the upper surface of the semiconductor substrate from the center of rotation thereof toward the outer periphery thereof due to a centrifugal force. In the comparative example, however, as shown in FIGS. 17 and 18, when forming the resist pattern in the second and later etching processes among the three etching processes in step S119, the opening OP already formed is filled with the resist solution. Thus, the resist solution supplied is less likely to uniformly expand on the upper surface of the semiconductor substrate from its rotation center toward the outer periphery thereof due to the centrifugal force. In such a case, the thickness of the resist film formed at the outer periphery of the semiconductor substrate becomes non-uniform, which might lead to unevenness in application of the resist film.

On the other hand, it can be proposed that the influence of the unevenness of the applied resist film is suppressed by increasing the thickness of the resist film. However, this is performed by increasing the amount of supply of the resist solution in forming the resist film, which results in an increase in consumption of the resist solution.

Further, in the comparative example, as shown in FIGS. 16 to 18, the ashing step for removing the resist pattern by ashing using, e.g., oxygen plasma has to be performed three times after formation of the opening OP in step S119. In the ashing step after the formation of the opening OP, the opening OP reaches the midway point of the interlayer insulating film IL in the thickness direction, which results in a short distance between the bottom surface of the opening OP and the upper surface of the photodiode PD. Thus, when performing the ashing step, the semiconductor element, such as the photodiode PD or the transfer transistor TX, might get damages, including defective crystals in, for example, an n-type semiconductor layer NW or a p-type semiconductor layer PW of the photodiode PD.

For example, when a defective crystal is formed in a semiconductor region included in the photodiode PD, a dark current tends to easily flow through the imaging element as the CMOS image sensor. The dark current means a phenomenon in which current flows even though light is not radiated. The increase in dark current leads to misunderstanding that the light is radiated, although the light is not radiated in fact, resulting in lighting up in error to generate a white spot to degrade an image displayed. As mentioned above, in the comparative example, for example, the defect crystal is formed in the semiconductor region included in the photodiode PD, causing the white spot to degrade the image displayed.

As disclosed in Patent Document 1, it can be proposed that in regions with the pixels for detecting different colored lights, dummy patterns serving as an etching stopper are formed in different heights over the respective photodiodes. Further, when etching a wiring layer positioned above the photodiode for each color, the etching is stopped at the upper surface of the dummy pattern, whereby the distance between the bottom part of the opening to the upper surface of the photodiode is varied in each of the regions with the pixel for detecting each of the different colored lights.

However, the dummy pattern disclosed in Patent Document 1 is made by forming a dummy pattern trench in the wiring layer, and filling the formed dummy pattern trench with metal material. The thus-formed dummy pattern is to block or reflect the light. Thus, after forming an opening as a waveguide hole, a part of the dummy pattern remaining at the bottom of the opening needs to be removed therefrom, which might lead to an increase in steps of the manufacturing procedure of the semiconductor device.

### Main Features and Effects of Embodiments

In the manufacturing method of the semiconductor device as the imaging element in the present embodiment, in each of the regions AR with the pixels for detecting different colored lights, a second film as the liner film is formed over a first film including the interlayer insulating film IL for covering the photodiode PD. Then, the opening OP is formed to reach the midway point of the first film while penetrating the second film. The second film is formed to have different thicknesses among the respective regions AR. The height position of the bottom surface of the opening OP in the region with the thinner second film is lower than that of the bottom surface of the opening OP in the region with the thicker second film.

In this way, in each of the pixels for detecting the different colored lights, the distance between the lower surface of the optical waveguide WG to the upper surface of the photodiode PD, that is, the distance by which the light emitted from the lower surface of the optical waveguide WG travels to enter the photodiode PD can be adjusted. Thus, the light traveling distance can be easily adjusted to equalize the light efficiency, that is, a ratio of a diameter of the lower surface of the optical waveguide WG to that of a region of the upper surface of the photodiode PD on which light emitted from the lower surface of the waveguide WG is incident among the pixels for detecting the different colored lights. Therefore, the performance of the semiconductor device as a CMOS image sensor can be easily improved.

In the present embodiment, as shown in FIG. 12, in step S19, the etching process for etching the liner film LF3, the interlayer insulating film IL2, the liner film LF2, the interlayer insulating film IL1, the liner film LF1, and the interlayer insulating film IL does not need to be performed three times like the comparative example, that is, has only to be performed one time. Thus, the number of the etching processes for the layers from the liner film LF3 to the interlayer insulating film IL can be decreased. Therefore, the manufacturing procedure of the semiconductor device can be simplified, which results in a decrease in manufacturing cost.

Alternatively, in the present embodiment, as shown in FIG. 12, in step S19, when forming the resist pattern, the resist film is formed while the opening is not formed. Thus, unlike the comparative example, the resist solution might not fill the opening already formed. When forming the resist film for forming the opening, the resist film can be prevented or suppressed from having a non-uniform thickness thereof around the outer periphery of the semiconductor substrate, which can prevent or suppress the occurrence of uneven application of the resist film.

To reduce the influence of the uneven application of the resist film, the thickness of the resist film does not need to be increased. Thus, the amount of supply of the resist solution can be decreased in forming the resist film, which can reduce the amount of use of the resist solution.

In the present embodiment, as shown in FIG. 12, in step S19, after forming the opening OP, the ashing process for removing the resist pattern by ashing using, e.g., oxygen plasma does not need to be performed three times, unlike the comparative example, and has only to be performed one time. Thus, when performing the ashing step, the n-type semiconductor layer NW and p-type semiconductor layer PW of the photodiode PD can be prevented or suppressed from getting the defective crystal, and the semiconductor element, such as the photodiode PD or transfer transistor TX, can also be prevented or suppressed from being damaged.

Thus, the present embodiment can prevent or suppress the occurrence of white spots due to the flow of dark current through the imaging element as the CMOS image sensor, which can prevent or suppress the degradation of the displayed image.

Although the invention made by the inventors has been specifically described based on the embodiment and modified examples, it is apparent that the invention is not limited to the above embodiments, and that various modifications and changes can be made without departing from the scope of the invention.

For example, as mentioned in the above description of the present embodiment, the thickness of the liner film LF1 included in the first wiring layer is varied among the respective regions ARr, ARg, and ARb, whereby the height position of the bottom surface of the opening OP differs among the respective regions ARr, ARg, and ARb. Alternatively, by varying the thickness of the liner film included in any of the wiring layers among the respective regions ARr, ARg, and ARb, through the liner film, the height position of the bottom surface of the opening OP reaching the midway point of the interlayer insulating film IL in the thickness direction may be varied. Thus, the thickness of the liner film LF2 included in the second wiring layer is varied among the respective regions ARr, ARg, and ARb, whereby the height position of the bottom surface of the opening OP also differs among the respective regions ARr, ARg, and ARb.

Alternatively, the thickness of the liner film LF3 is varied among the respective regions ARr, ARg, and ARb, whereby the height position of the bottom surface of the opening OP can also differ among the respective regions ARr, ARg, and ARb.

The preferred embodiments have explained above the manufacturing method of the semiconductor device as the imaging element with three types of pixels for detecting different colored lights. However, the manufacturing method of the semiconductor device in the present embodiment can be applied to a manufacturing method of the semiconductor device as the imaging element with two types of pixels for respectively detecting different colored lights. Alternatively, the manufacturing method of the semiconductor device in the present embodiment can be applied to a manufacturing method of a semiconductor device as the imaging element with four or more types of pixels for respectively detecting different colored lights.

Further, the present embodiment has described the manufacturing method of the semiconductor device as the imaging element with the photodiode serving as the photoelectric conversion element. However, the manufacturing method of the semiconductor device in the present embodiment can be applied to a manufacturing method of a semiconductor device as the imaging element or device including various photoelectric conversion elements, such as a charge coupled device (CCD) including the photoelectric conversion element.

What is claimed is:

1. A method for manufacturing a semiconductor device, comprising the steps of:
(a) forming a first photoelectric conversion element in a first region of a main surface of a semiconductor substrate, the first photoelectric conversion element being adapted to receive a first incident light and to convert the first incident light into electric charge, and forming a second photoelectric conversion element in a second region of the main surface of the semiconductor substrate, the second photoelectric conversion element being adapted to receive a second incident light in a different color from that of the first incident light and to convert the second incident light into electric charge;
(b) forming a first film over the first photoelectric conversion element and the second photoelectric conversion element;
(c) forming a second film over the first film;
(d) forming, in the first region, a first opening that reaches a midway point of a part of the first film positioned above the first photoelectric conversion element while penetrating the second film, and forming, in the second region, a second opening that reaches a midway point of a part of the first film positioned above the second photoelectric conversion element while penetrating the second film, by etching the second film and the first film;
(e) forming a third film to fill the first opening and the second opening therewith,
wherein in the step (e), a first optical waveguide is provided to guide the first incident light to the first photoelectric conversion element, the first optical waveguide being formed of a part of the third film filling the first opening, and a second optical waveguide is provided to guide the second incident light to the second photoelectric conversion element, the second optical waveguide being formed of a part of the third film filling the second opening, and
wherein in the step (c), the second film is formed such that a first thickness of a part of the second film positioned above the first photoelectric conversion element in the first region is thinner than a second thickness of a part of the second film positioned above the second photoelectric conversion element in the second region, whereby a first height position of a bottom surface of the first opening is lower than a second height position of a bottom surface of the second opening.

2. The method for manufacturing a semiconductor device according to claim 1, wherein the step (c) comprises the steps of:
(c1) depositing the second film over the first film; and
(c2) after the step (c1), etching the second film such that the first thickness is thinner than the second thickness.

3. The method for manufacturing a semiconductor device according to claim 1, wherein in the step (d), the second opening is formed when forming the first opening.

4. The method for manufacturing a semiconductor device according to claim 1, wherein the second film is made of silicon carbonitride.

5. The method for manufacturing a semiconductor device according to claim 4, wherein in the step (d), the second film and the first film are etched using gas containing fluorine.

6. The method for manufacturing a semiconductor device according to claim 1, wherein in the step (a), a third photoelectric conversion element is formed in a third region of the main surface of the semiconductor substrate, the third photoelectric conversion element being adapted to receive a third incident light in a different color from those of the first and second incident lights and to convert the third incident light into electric charge,
wherein in the step (b), the first film is formed over the third photoelectric conversion element,
wherein in the step (d), a third opening is formed in the third region to reach a midway point of apart of the first film positioned above the third photoelectric conversion element while penetrating the second film,
wherein in the step (e), the third film is formed to fill the third opening, and a third optical waveguide is provided to guide the third incident light to the third photoelectric conversion element, the third optical waveguide being formed of a part of the third film filling the third opening,
wherein a wavelength of the first incident light is longer than that of the second incident light,
wherein the wavelength of the second incident light is longer than that of the third incident light,
wherein in the step (c), the second film is formed such that the second thickness is thinner than a third thickness of a part of the second film positioned above the third photoelectric conversion element in the third region, and
wherein the second height position is lower than a third height position of a bottom surface of the third opening.

7. The method for manufacturing a semiconductor device according to claim 1, further comprising the step of:
(f) after the step (c) and before the step (d), forming a fourth film over the second film,
wherein in the step (d), the fourth film, the second film, and the first film are etched, whereby the first opening is formed in the first region to reach the midway point of the part of the first film positioned above the first photoelectric conversion element while penetrating the fourth film and the second film, and the second opening is formed in the second region to reach the midway point of the part of the first film positioned above the second photoelectric conversion element while penetrating the fourth film and the second film.

8. The method for manufacturing a semiconductor device according to claim 7, wherein the second region is adjacent to the first region,
wherein the fourth film includes a plurality of insulating layers, and
wherein a wiring layer is formed of the insulating layers positioned between the first opening and the second opening, and a wiring formed inside any one of the insulating layers positioned between the first opening and the second opening.

9. The method for manufacturing a semiconductor device according to claim 1, wherein the first photoelectric conversion element is a first photodiode, and
wherein the second photoelectric conversion element is a second photodiode.

10. The method for manufacturing a semiconductor device according to claim 1, further comprising the step of:
(g) forming a first color filter for allowing the first incident light to pass therethrough, over the first optical waveguide, and forming a second color filter for allowing the second incident light to pass therethrough, over the second optical waveguide.

11. The method for manufacturing a semiconductor device according to claim 7, wherein the step (d) comprises the steps of:
(d1) forming a resist film over the fourth film;
(d2) exposing and patterning the resist film, and developing the patterned resist film to thereby form, in the first region, a fourth opening that reaches a part of the fourth film positioned above the first photoelectric conversion element while penetrating the resist film, and to thereby form, in the second region, a fifth opening that reaches a part of the fourth film positioned above the second photoelectric conversion element while penetrating the resist film, whereby a resist pattern made of the resist film is formed with the fourth and fifth openings formed therein;
(d3) etching the fourth film, the second film, and the first film using the resist pattern as a mask to thereby form the first opening and the second opening; and
(d4) removing the resist pattern by ashing.
